(19) United States
(12) Patent Application Publication
(10) Pub. No.: US 2012/0308715 A1
(43) Pub. Date: Dec. 6, 2012

(54) COATING APPARATUS AND COATING METHOD

(75) Inventors: Hidenori Miyamoto, Kawasaki-shi (JP); Tsutomu Sahoda, Kawasaki-shi (JP)

(73) Assignee: TOKYO OHKA KOGYO CO., LTD., Kawasaki-shi (JP)

(21) Appl. No.: 13/484,728

(22) Filed: May 31, 2012

Related U.S. Application Data
(60) Provisional application No. 61/492,666, filed on Jun. 2, 2011.

(51) Int. Cl. H01L 31/18

(52) U.S. Cl. 427/74; 118/602

(57) ABSTRACT

A coating apparatus including: a coating part having a nozzle which ejects a liquid material containing an oxidizable metal and a solvent to a substrate; a supplying system which supplies the liquid material to the coating part; and a recycling system which recovers the liquid material from at least one of the supplying system and the coating part, and supplies the recovered liquid material to at least one of the supplying system and the coating part.

Priority is claimed on Provisional Application No. 61/492,666, filed on Jun. 2, 2011, the content of which is incorporated herein by reference.

### FIELD OF THE INVENTION

The present invention relates to a coating apparatus and a coating method.

### DESCRIPTION OF THE RELATED ART

A CIGS solar cell or a CZTS solar cell formed by semiconductor materials including a metal such as Cu, Ge, Sn, Pb, Sb, Si, Ga, In, Ti, Zn, and a combination thereof, and a chalcogen element such as S, Se, Te, and a combination thereof has been attracting attention as a solar cell having high conversion efficiency (for example, see Patent Documents 1 to 3).

For example, a CIGS solar cell has a structure in which a film including four types of semiconductor materials, namely, Cu, In, Ga, and Se is used as a light absorbing layer (photoelectric conversion layer). Further, for example, a CZTS solar cell has a structure in which a film including four types of semiconductor materials, namely, Cu, Zn, Sn, and Se is used as a light absorbing layer (photoelectric conversion layer). In such solar cells, a configuration is known in which a back electrode made of molybdenum is provided on a substrate such a glass, and the aforementioned light absorbing layer is provided on the back electrode.

In a CIGS solar cell or a CZTS solar cell, since it is possible to reduce the thickness of the light absorbing layer compared to a conventional solar cell, it is easy to install the CIGS solar cell on a curved surface and to transport the CIGS solar cell. For this reason, it is expected that CIGS solar cells can be used in various application fields as a high-performance, flexible solar cell. As a method of forming the light absorbing layer, a method of forming the light absorbing layer through depositing or sputtering is conventionally known (for example, see Patent Documents 2 to 5).

### DOCUMENTS OF RELATED ART

### Patent Documents

[Patent Document 1] Japanese Unexamined Patent Application, First Publication No. Hei 11-340482
[Patent Document 2] Japanese Unexamined Patent Application, First Publication No. 2005-51224
[Patent Document 3] Published Japanese Translation No. 2009-537997 of the PCT International Publication
[Patent Document 4] Japanese Unexamined Patent Application, First Publication No. Hei 1-231313
[Patent Document 5] Japanese Unexamined Patent Application, First Publication No. Hei 11-273783

### SUMMARY OF THE INVENTION

In contrast, as the method of forming the light absorbing layer, the present inventor proposes a method of coating the semiconductor materials in the form of a liquid material on a substrate. In such a method of forming the light absorbing layer by coating the semiconductor materials in the form of a liquid material, the following problems arise.

In the case of supplying a liquid material to a nozzle, when the liquid material is retained between the supply source and the nozzle, there is a possibility that fluctuation occurs in the concentration of the components of the liquid material. When the liquid material is coated on a substrate in a state where there is fluctuation in the concentration of the components, there is a possibility that the film property of the coating film formed on the substrate varies.

The present invention takes the above circumstances into consideration, with an object of providing a coating apparatus and a coating method capable of preventing variation in the film property of the coating film.

A coating apparatus according to a first aspect of the present invention includes: a coating part having a nozzle which ejects a liquid material containing an oxidizable metal and a solvent to a substrate; a supplying system which supplies the liquid material to the coating part; and a recycling system which recovers the liquid material from at least one of the supplying system and the coating part, and supplies the recovered liquid material to at least one of the supplying system and the coating part.

According to the present invention, by virtue of being provided with a recycling system which recovers the liquid material from at least one of the supplying system and the coating part, and supplies the recovered liquid material to at least one of the supplying system and the coating part, the liquid material can be prevented from being retained between the supplying system and the coating part. As a result, the concentration of the components contained in the liquid material can be prevented from being changed, thereby preventing variation in the film properties of the coating film.

In the coating apparatus, the recycling system may include a first recovery part which recovers the liquid material ejected from the nozzle.

In this embodiment, by virtue of the first recovery part recovering the liquid material ejected from the nozzle, the liquid material can be utilized without waste.

In the coating apparatus, the recycling system may include a second recovery part which recovers the liquid material held inside the nozzle.

In this embodiment, by virtue of the second recovery part recovering the liquid material held inside the nozzle, the liquid material can be prevented from being retained inside the nozzle.

In the coating apparatus, the nozzle may have a vent part which communicates the inside and outside of the nozzle, and the second recovery part may recover the liquid material via the vent part.

In this embodiment, by virtue of the second recovery part recovering the liquid material via the vent part which communicates the inside and outside of the nozzle, the liquid material can be prevented from being retained in the vicinity of the vent part.

In the coating apparatus, the supplying system may have a flow path connected to the coating part and allows the liquid material to flow therethrough, and the recycling system may have a third recovery part which recovers the liquid material from the flow path.

In this embodiment, by virtue of the third recovery part recovering the liquid material from the flow path through which the liquid material is allowed to flow, the liquid material can be prevented from being retained in the flow path.

In the coating apparatus, the supplying system may have a storing part which stores the liquid material, and the recycling system may have a second flow path which transfers the recovered liquid material to the storing part.

In this embodiment, by virtue of transferring the recovered liquid material to the storing part via the second flow path, the liquid material can be prevented from being retained in the storing part.

In the coating apparatus, the storing part may have a stirrer which stirs the liquid material stored in the storing part.

In this embodiment, by virtue of the liquid material stored in the storing part being stirred by a stirrer, the liquid material can be prevented from being retained in the storing part.

In the coating apparatus, the supplying system may have a degassing part which removes a gaseous component contained in the liquid material, and the recycling system may have a third flow path which transfers the recovered liquid material to the degassing part.

In this embodiment, by virtue of the recovered liquid material being transferred to the degassing part via the third flow path, degassing treatment of the liquid material can be reliably conducted.

In the coating apparatus, the supplying system may have a storing part which stores the liquid material, and the degassing part may be provided on a downstream side of a supply path of the liquid material, relative to the storing part.

In this embodiment, by virtue of the degassing part being provided on a downstream side of a supply path of the liquid material, relative to the storing part, the liquid material can be subjected to a degassing treatment while supplying the liquid material in the storing part to the coating part.

In the coating apparatus, the supplying system may have a storing part which stores the liquid material, and the degassing part is connected to the storing part via a second path which is different from a supply path of the liquid material.

In this embodiment, by virtue of the degassing part being connected to the storing part via a second path which is different from a supply path of the liquid material, the liquid material can be efficiently transferred to the coating part and the degassing part.

A coating method according to a second aspect of the present invention includes: an ejection step in which a liquid material containing an oxidizable metal and a solvent is ejected from a nozzle provided on a coating part to a substrate; a supplying step in which the liquid material is supplied to the coating part using a supplying system for the liquid material; and a recycling step in which the liquid material is recovered from at least one of the supplying system and the coating part, and the recovered liquid material is supplied to at least one of the supplying system and the coating part.

According to the present invention, by virtue of recovering the liquid material from at least one of the supplying system and the coating part, and supplying the recovered liquid material to at least one of the supplying system and the coating part, the liquid material can be prevented from being retained between the supplying system and the coating part. As a result, the concentration of the components contained in the liquid material can be prevented from being changed, thereby preventing variation in the film properties of the coating film.

In the coating method, the recycling step may include a first recovering step in which the liquid material ejected from the nozzle is recovered.

In this embodiment, by virtue of recovering the liquid material ejected from the nozzle, the liquid material can be utilized without waste.

In the coating method, the recycling step may include a second recovering step in which the liquid material held inside the nozzle is recovered.

In this embodiment, by virtue of recovering the liquid material held inside the nozzle, the liquid material can be prevented from being retained inside the nozzle.

In the coating method, the nozzle may have a vent part which communicates the inside and outside of the nozzle, and the second step may include recovering the liquid material via the vent part.

In this embodiment, by virtue of recovering the liquid material via the vent part which communicates the inside and outside of the nozzle, the liquid material can be prevented from being retained in the vicinity of the vent part.

In the coating method, the supplying step may include allowing the liquid material to flow via a flow path connected to the coating part, and the recycling step may include a third recovery step in which the liquid material is recovered from the flow path.

In this embodiment, by virtue of recovering the liquid material from the flow path through which the liquid material is allowed to flow, the liquid material can be prevented from being retained in the flow path.

In the coating method, the supplying step may include a storing step in which the liquid material is stored in a storing part.

In this embodiment, by virtue of transferring the recovered liquid material to the storing part, the liquid material can be prevented from being retained in the storing part.

In the coating method, the storing step may include a stirring step in which the stored liquid material is stirred.

In this embodiment, by virtue of stirring the liquid material stored in the storing part, the liquid material can be prevented from being retained in the storing part.

In the coating method, the supplying step may include a degassing step in which a gaseous component contained in the liquid material is removed.

In this embodiment, by virtue of removing a gaseous component contained in the liquid material, the film quality of the coating film of the liquid material can be prevented from being deteriorated.

In the coating method, the supplying step may include a storing step in which the liquid material is stored in a storing part, and the degassing step may include removing the gaseous component on a downstream side of a supply path of the liquid material, relative to the storing part.

In this embodiment, by virtue of conducting a degassing treatment on a downstream side of a supply path of the liquid material, relative to the storing part, the liquid material can be subjected to the degassing treatment while supplying the liquid material in the storing part to the coating part.

In the coating method, the supplying step may include a storing step in which the liquid material is stored in a storing part, and the degassing step may include removing the gaseous component on a second path which is connected to the storing part and is different from a supply path of the liquid material.

In this embodiment, by virtue of conducting a degassing treatment on a second path which is different from a supply path of the liquid material, the liquid material can be efficiently transferred to the coating part and the degassing part.

According to the present invention, variation in the film property of the coating film can be prevented.

### BRIEF DESCRIPTION OF THE DRAWINGS

FIG. 1 is a diagram showing an entire configuration of a coating apparatus according to one embodiment of the present invention.

FIG. 2 is a diagram showing an entire configuration of a coating apparatus according to the present embodiment.

FIG. 3 is a diagram showing a configuration of a nozzle according to the present embodiment.

FIG. 4 is a diagram showing a configuration of part of a coating apparatus according to the present embodiment.

FIG. 5 is a piping diagram showing a flow path configuration of the coating part according to the present embodiment.

FIG. 6 is a diagram showing a configuration of a vacuum drying part according to the present embodiment.

FIG. 7 is a diagram showing a configuration of part of a baking part according to the present embodiment.

FIG. 8 is a diagram showing a step in a coating treatment performed by a coating apparatus according to the present embodiment.

FIG. 9 is a diagram showing a step in a coating treatment performed by a coating apparatus according to the present embodiment.

FIG. 10 is a diagram showing a step in a coating treatment performed by a coating apparatus according to the present embodiment.

FIG. 11 is a diagram showing a step in a coating treatment performed by a coating apparatus according to the present embodiment.

FIG. 12 is a diagram showing a step in a coating treatment performed by a coating apparatus according to the present embodiment.

FIG. 13 is a diagram showing a step in a baking treatment performed by a coating apparatus according to the present embodiment.

FIG. 14 is a diagram showing a step in a baking treatment performed by a coating apparatus according to the present embodiment.

FIG. 15 is a diagram showing a step in a baking treatment performed by a coating apparatus according to the present embodiment.

FIG. 16 is a diagram showing a step in a baking treatment performed by a coating apparatus according to the present embodiment.

FIG. 17 is a diagram showing a step in a baking treatment performed by a coating apparatus according to the present embodiment.

FIG. 18 is a diagram showing a step in a supplying treatment of a liquid material performed by a coating apparatus according to the present embodiment.

FIG. 19 is a diagram showing a step in a supplying treatment of a liquid material performed by a coating apparatus according to the present embodiment.

FIG. 20 is a diagram showing a step in a supplying treatment of a liquid material performed by a coating apparatus according to the present embodiment.

FIG. 21 is a diagram showing a step in a supplying treatment of a liquid material performed by a coating apparatus according to the present embodiment.

FIG. 22 is a diagram showing a configuration of a coating apparatus according to a modified example of the present invention.

FIG. 23 is a diagram showing a configuration of a coating apparatus according to a modified example of the present invention.

FIG. 24 is a diagram showing a configuration of a coating apparatus according to a modified example of the present invention.

FIG. 25 is a diagram showing a configuration of a coating apparatus according to a modified example of the present invention.

FIG. 26 is a diagram showing a configuration of a coating apparatus according to a modified example of the present invention.

FIG. 27 is a diagram showing a configuration of a coating apparatus according to a modified example of the present invention.

FIG. 28 is a diagram showing a configuration of a coating apparatus according to a modified example of the present invention.

### MODE FOR CARRYING OUT THE INVENTION

Hereinafter, one embodiment of the present invention will be described with reference to the accompanying drawings.

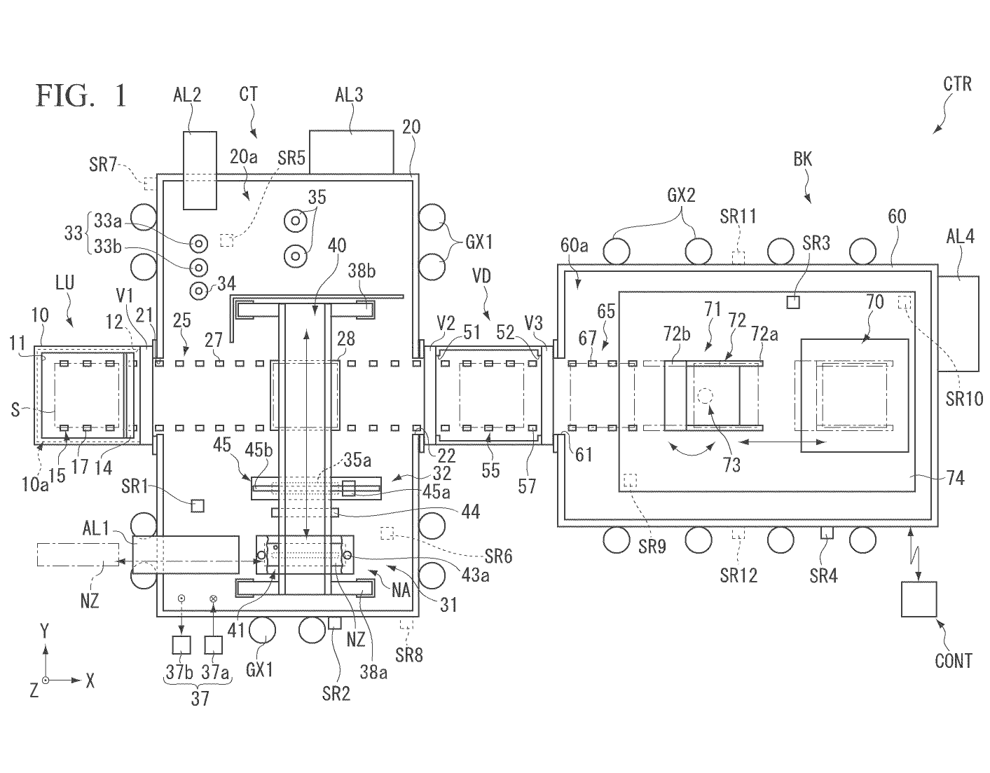

FIG. 1 is a schematic diagram showing a configuration of a coating apparatus CTR according to one embodiment of the present invention.

As shown in FIG. 1, the coating apparatus CTR is an apparatus which applies a liquid material to a substrate S. The coating apparatus CTR includes a substrate loading/unloading part LU, a coating part CT, a vacuum drying part VD, a baking part BK and a control part CONT. The coating apparatus CTR is used, for example, by being disposed on a floor FL in a factory. The coating apparatus may have a configuration in which the coating apparatus is accommodated in one room, or a configuration in which the coating apparatus is divisionally accommodated in a plurality of rooms. In the coating apparatus CTR, the substrate loading/unloading part LU, the coating part CT, the vacuum drying part VD and the baking part BK are arranged in this order in one direction. With respect to the configuration of the coating apparatus CTR, it is not particularly limited that the substrate loading/unloading part LU, the coating part CT, the vacuum drying part VD and the baking part BK are arranged in this order in one direction. For example, the substrate loading/unloading part LU may be divided into a substrate loading part (not shown) and a substrate unloading part (not shown). Further, the vacuum drying part VD may be omitted. Needless to say, the aforementioned parts may not be arranged in one direction, and a configuration may be employed in which the aforementioned parts are arranged to be stacked in a vertical or horizontal direction with a robot (not shown) disposed at a central position.

In the respective drawings as below, upon describing the configuration of a substrate treating apparatus according to the present embodiment, for the purpose of simple marking, an XYZ coordinate system is used to describe the directions in the drawings. In the XYZ coordinate system, the plane parallel to the floor is regarded as the XY plane. On the XY plane, the direction in which the components of the coating apparatus CTR (the substrate loading/unloading part LU, the coating part CT, the vacuum drying part VD and the baking part BK) are arranged is marked as the X direction, and the direction perpendicular to the X direction on the XY plane is marked as the Y direction. The direction perpendicular to the XY plane is marked as the Z direction. In the X, Y, and Z directions, the arrow direction in the drawing is the + direction, and the opposite direction of the arrow direction is the − direction.

In this embodiment, as the substrate S, for example, a plate-shaped member made of glass, resin, or the like may be used. Further, in this embodiment, molybdenum is sputtered on the substrate S as a back electrode. Needless to say, any other electroconductive material may be used as a back electrode. Explanation will be given below, taking an example of a substrate having a size of 330 mm×330 mm as viewed in the Z direction. The size of the substrate is not limited to 330 mm×330 mm. For example, as the substrate S, a substrate having a size of 125 mm×125 mm may be used, or a substrate having a size of 1 m×1 m may be used. Needless to say, a substrate having a size larger than the aforementioned sizes or a substrate having a size smaller than the aforementioned sizes may be appropriately used.

In this embodiment, as the liquid material to be applied to the substrate S, for example, a liquid composition is used which includes a solvent such as hydrazine and oxidizable metals such as a combination of copper (Cu), indium (In), gallium (Ga), and selenium (Se) or a combination of copper (Cu), zinc (Zn), tin (Sn) and selenium (Se). The liquid composition includes a metal material for forming a light absorbing layer (photoelectric conversion layer) of a CIGS solar cell or a CZTS solar cell.

In the present embodiment, the liquid composition contains a substance for obtaining the grain size of a light absorbing layer of a CIGS solar cell or a CZTS solar cell. Needless to say, as the liquid material, a liquid material in which another oxidizable metal is dispersed in the solution may be used.

(Substrate Loading/Unloading Part)

The substrate loading/unloading part LU loads a substrate S prior to being treated on the coating part CT, and unloads the treated substrate S from the coating part CT. The substrate loading/unloading part LU has a chamber 10. The chamber 10 is formed in the shape of a rectangular box. Inside the chamber 10, an accommodation room 10a capable of accommodating the substrate S is formed. The chamber 10 has a first opening 11, a second opening 12 and a lid portion 14. The first opening 11 and the second opening 12 communicates the accommodation room 10a with the outside of the chamber 10.

The first opening 11 is formed on a +Z-side face of the chamber 10. The first opening 11 is formed to have a size larger than the size of the substrate S as viewed in the Z direction. The substrate S to be taken out of the chamber 10 or the substrate S to be accommodated in the accommodation room 10a is place into or taken out of the substrate loading/unloading part LU through the first opening 11.

The second opening 12 is formed on a +X-side face of the chamber 10. The second opening 12 is formed to have a size larger than the size of the substrate S as viewed in the X direction. The substrate S supplied to the coating part CT or the substrate S returned from the coating part CT is place into or taken out of the substrate loading/unloading part LU through the second opening 12.

The lid portion 14 opens or closes the first opening 11. The lid portion 14 is formed in the shape of a rectangular plate. The lid portion 14 is attached to a +X-side edge of the first opening 11 via a hinge portion (not shown). Thus, the lid portion 14 is rotatable around the Y-axis, with the +X-side edge of the first opening 11 as the center. By rotating the lid portion 14 around the Y-axis, the first opening 11 can be opened or closed.

The accommodation room 10a is provided with a substrate transporting part 15. The substrate transporting part 15 includes a plurality of rollers 17. The rollers 17 are arranged in a pair in the Y-direction, and a plurality of the pairs are arranged in the X-direction.

Each of the rollers 17 is adapted to be rotatable about the Y direction serving as the central axis. The plurality of rollers 17 are formed to have the same diameter, and the +Z-side end of the plurality of rollers 17 are arranged on a same plane parallel to the XY plane. Thus, the plurality of rollers 17 are capable of supporting the substrate S in a state where the substrate S is parallel to the XY plane.

The rotation of each of the rollers 17 is controlled, for example, by a roller-rotation control part (not shown). By rotating each of the rollers 17 clockwise or anti-clockwise around the Y-axis in a state where the substrate S is supported by the plurality of rollers 17, the substrate transporting part 15 can transport the substrate S in an X-direction (+X-direction or −X-direction). As the substrate transporting part 15, a float transporting part (not shown) may be used to lift the substrate for transportation.

(Coating Part)

The coating part CT performs the coating treatment of the liquid material on the substrate S. The coating part CT includes a chamber 20 and a base BC. The coating part CT has a configuration in which the chamber 20 is mounted on the base BC placed on the floor FL.

The chamber 20 is formed in the shape of a rectangular box. Inside the chamber 20, a treatment room 20a is formed. The chamber 20 has a first opening 21 and a second opening 22. The first opening 21 and the second opening 22 communicates the treatment room 20a with the outside of the chamber 20.

The first opening 21 is formed on a −X-side face of the chamber 20. The second opening 22 is formed on a +X-side face of the chamber 20. The first opening 21 and the second opening 22 are formed to have a size which allows the substrate S to pass through. The substrate S is placed in or taken out of the chamber 20 through the first opening 21 and the second opening 22.

The treatment room 20a is provided with an ejection part 31, a maintenance part 32, a liquid material supply part 33, a washing liquid supply part 34, a waste liquid storing part 35, a gas supply/exhaust part 37 and a substrate transporting part 25.

The ejection part 31 has a nozzle NZ, a treatment stage 28 and a nozzle actuator NA.

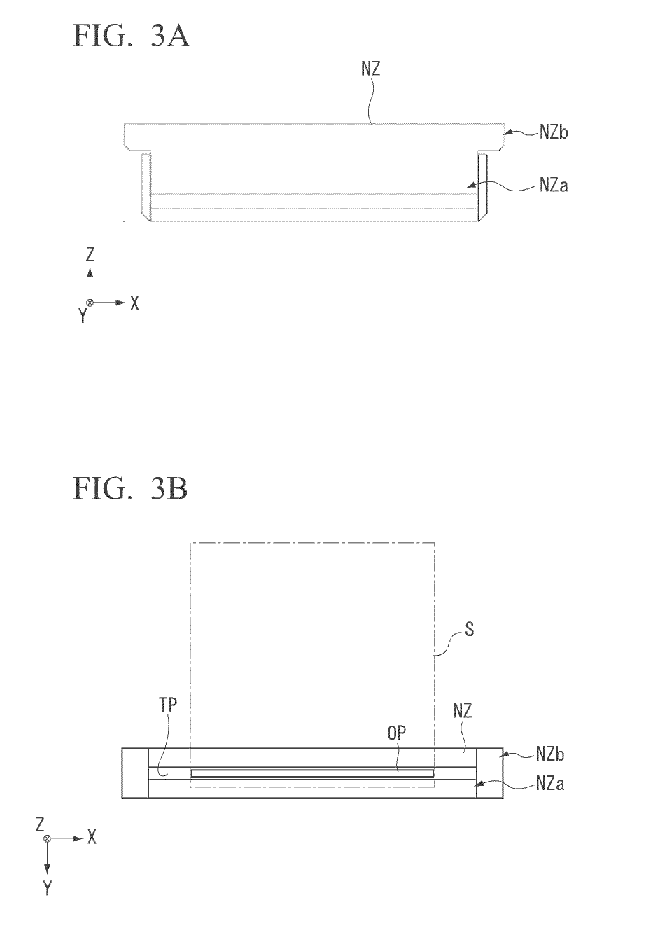

FIG. 3(a) and FIG. 3(b) are diagrams showing a configuration of the slit nozzle NZ.

As shown in FIG. 3(a), the nozzle NZ is formed to have an elongate shape, and is arranged such that the lengthwise direction thereof is in parallel to the X direction. The nozzle NZ has a main part NZa and a protruding part NZb. The main part NZa is a housing capable of accommodating the liquid material inside thereof. The main part NZa is made of, for example, a material containing titanium or a titanium alloy. The protruding part NZb is formed to protrude from the main part NZa on the +X-side and the −X-side. The protruding part NZb is held by part of the nozzle actuator NA.

FIG. 3(b) shows the configuration when the nozzle NZ is viewed from the −Z direction side thereof.

As shown in FIG. 3(b), the nozzle NZ has an ejection opening OP on the −Z-side end (tip TP) of the main part NZa. The ejection opening OP is an opening for ejecting a liquid material. The ejection opening OP is formed as a slit elongating in the X direction. The ejection opening OP is formed, for example, so that the longitudinal direction thereof is substantially equal to the X-direction dimension of the substrate S.

The nozzle NZ ejects, for example, a liquid material in which four types of metals, namely, Cu, In, Ga, and Se are mixed with a predetermined composition ratio. The nozzle NZ is connected to a liquid supply part 33 via a connection pipe or the like (not shown). The nozzle NZ includes a holding part which holds the liquid material therein. A temperature control part which controls the temperature of the liquid material held by the holding part may be provided.

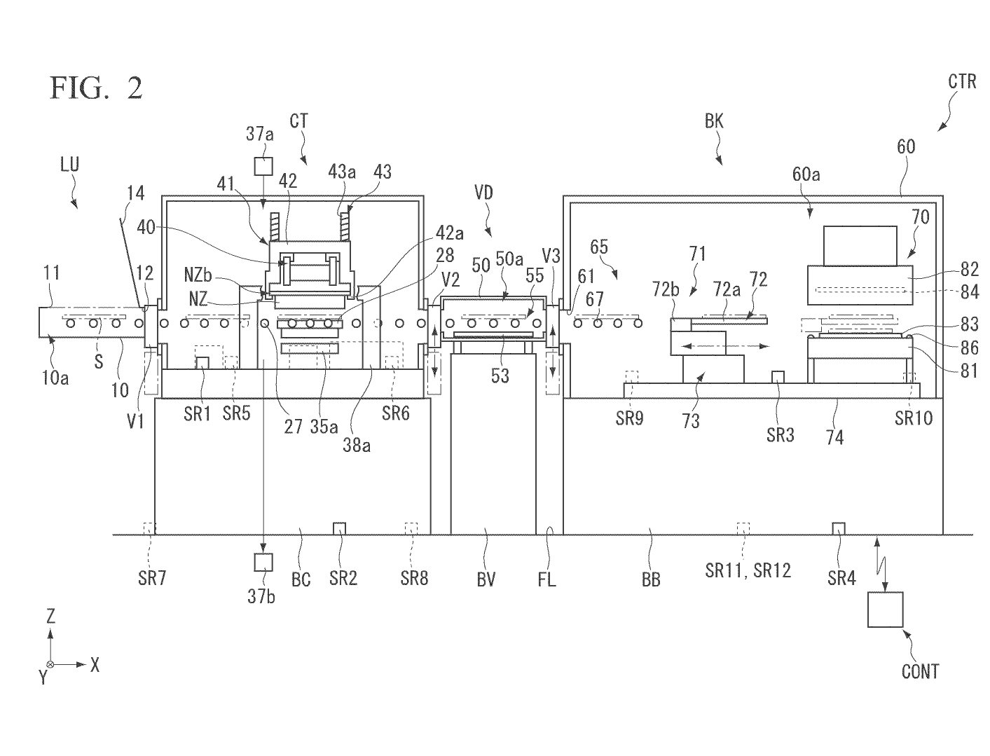

Returning to FIG. 1 and FIG. 2, the substrate S to be subjected to a coating treatment is mounted on the treatment stage 28. The +Z-side face of the treatment stage 28 is a substrate mounting face where the substrate S is mounted. The substrate mounting face is formed to be in parallel with the XY plane. The treatment stage 28 is made of, for example, stainless steel.

The nozzle actuator NA moves the nozzle NZ in the X direction. The nozzle actuator NA has a stator 40 and a mover 41 which constitutes a linear motor mechanism. As the nozzle actuator NA, any other actuator having another configuration such as a ball screw configuration may be used. The stator 40 is elongated in the Y direction. The stator 40 is supported by a support frame 38. The support frame 38 has a first frame 38a and a second frame 38b. The first frame 38a is provided on a −Y-side end portion of the treatment room 20a. The second frame 38b is provided in the treatment room 20a such that the treatment stage 28 is positioned between the first frame 38a and the second frame 38b.

The mover 41 is movable along the direction where the stator 40 is elongated (Y direction). The mover 41 has a nozzle supporting member 42 and an elevator part 43. The nozzle supporting member 42 is formed in the shape of a gate, and has a holding part 42a which holds the protruding part NZb of the nozzle NZ. The nozzle supporting member 42 integrally moves with the elevator part 43 along the stator 40 between the first frame 38a and the second 38b in the Y direction. Thus, the nozzle NZ held by the nozzle supporting member 42 moves in the Y direction over the treatment stage 28. The nozzle supporting member 42 moves along the elevation guide 43a of the elevator part 43 in the Z direction. The mover 41 has an actuator source (not shown) which moves the nozzle supporting member 42 in the Y direction and the Z direction.

The maintenance part 32 is where the maintenance of the nozzle NZ is performed. The maintenance part 32 has a nozzle standby part 44 and a nozzle-tip control part 45.

The nozzle standby part 44 has a dipping part (not shown) where the tip TP of the nozzle NZ is dipped to prevent it from drying, and a discharge part (not shown) which discharges the liquid material held within the nozzle NZ when the nozzle NZ is changed or the liquid material to be supplied to the nozzle NZ is changed.

The nozzle-tip control part 45 adjusts the conditions of the nozzle tip by washing the tip TP of the nozzle NZ and the vicinity thereof, and conducting preliminary ejection from the ejection opening OP of the nozzle NZ. The nozzle-tip control part 45 has a wiping part 45a which wipes the tip TP of the nozzle NZ and a guide rail 45b which guides the wiping part 45a. The nozzle-tip control part 45 is provided with a waste liquid accommodation part 35a which accommodates the liquid material discharged from the nozzle NZ and the washing liquid used for washing the nozzle NZ.

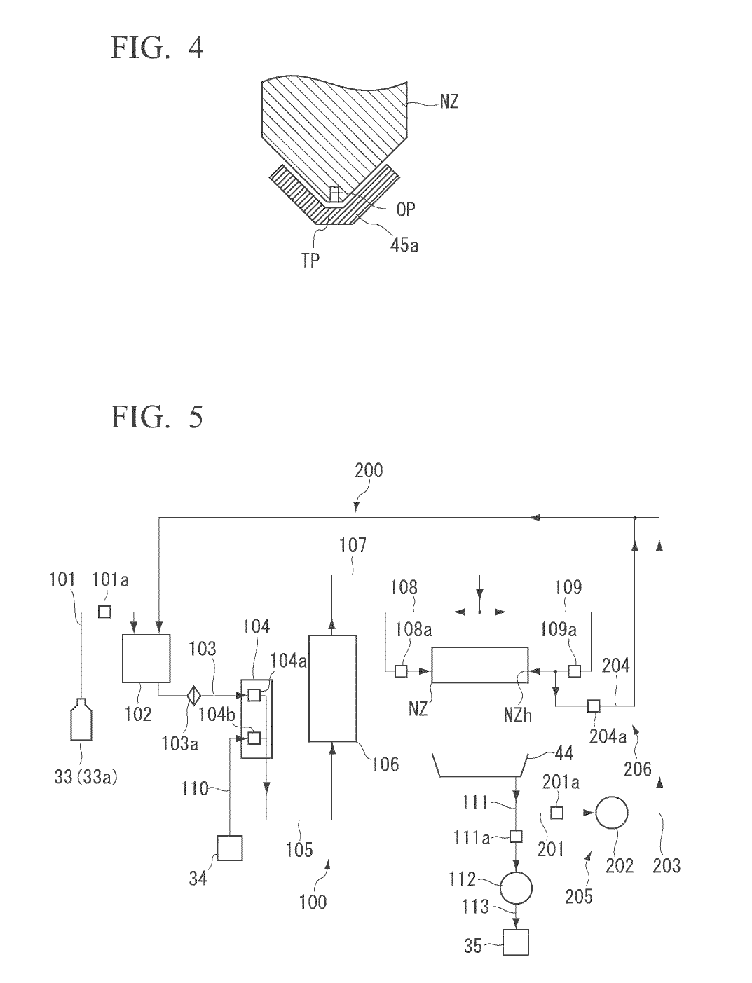

FIG. 4 is a diagram showing the cross-sectional shape of the nozzle NZ and the nozzle-tip control part 45. As shown in FIG. 4, the wiping part 45a is formed to cover the tip TP of the nozzle NZ and part of the inclined plane on the tip TP-side in the cross-sectional view.

The guide rail 45b extends in the X direction to cover the opening OP of the nozzle NZ. The wiping part 45a is adapted to be movable by an actuator source (not shown) along the guide rail 45b in the X direction. By moving the wiping part 45a in the X direction while being in contact with the tip TP of the nozzle NZ, the tip TP can be wiped.

The liquid material supply part 33 has a first liquid material accommodation part 33a and a second liquid material accommodation part 33b. The first liquid material accommodation part 33a and the second liquid material accommodation part 33b accommodate the liquid material to be applied to the substrate S. Further, the first liquid material accommodation part 33a and the second liquid material accommodation part 33b are capable of accommodating a plurality of different types of liquid materials.

The washing liquid supply part 34 accommodates a washing liquid which washes various parts of the coating part, such as the inside of the nozzle NZ and the nozzle-tip control part 45. The washing liquid supply part 34 is connected to the inside of the nozzle NZ and the nozzle-tip control part 45 via a pipe and a pump (which are not shown).

The waste liquid storing part 35 collects the liquid ejected from the nozzle NZ and is not reused. The nozzle-tip control part 45 may have a configuration in which the part which conducts the preliminary ejection and the part which washes the tip TP of the nozzle NZ are individually provided. Alternatively, the preliminary ejection may be conducted at the nozzle standby part 44.

The gas supply/exhaust part 37 has a gas supply part 37a and a gas exhaust part 37b. The gas supply part 37a supplies an inert gas such as a nitrogen gas or an argon gas to the treatment room 20a. The gas exhaust part 37b suctions the treatment room 20a, and discharges the gas in the treatment room 20a outside the chamber 20.

The substrate transporting part 25 transports the substrate S inside the treatment room 20a. The substrate transporting part 25 includes a plurality of rollers 27. The rollers 27 are arranged in the X-direction to be intersected into two lines by a central portion of the treatment room 20a in the Y-direction. The rollers 27 arranged in each line support the +Y-side end and −Y-side end of the substrate S.

By rotating each of the rollers 27 clockwise or anti-clockwise around the Y-axis in a state where the substrate S is supported by the plurality of rollers 27, the substrate S supported by each of the rollers 27 is transported in an X-direction (+X-direction or −X-direction). A float transporting part (not shown) may be used to lift the substrate for transportation.

FIG. 5 is a piping diagram showing a flow path configuration of the liquid material, the washing liquid and the gas in the coating part CT.

As shown in FIG. 5, the coating part CT is provided with a supply system 100 and a recycle system 200. The supply system 100 supplies the liquid material to the nozzle NZ. The recycle system 200 recovers the liquid material from at least one of the supply system 100 and the nozzle NZ, and supplies the recovered liquid material to at least one of the supply system 100 and the nozzle NZ.

The supply system 100 supplies the liquid material from the liquid material supply part 33 to the nozzle NZ. In the supply system 100, the liquid material supply part 33 is on the upstream side, and the nozzle NZ is on the downstream side. The supply system 100 has a pipe 101, an air vent tank 102, a pipe 103, a connection switch 104, a pipe 105, a discharge pump 106, a pipe 107, nozzle pipes 108 and 109, a pipe 110, a pipe 111, a chemical pump 112 and a pipe 113.

The upstream-side end of the pipe 101 is connected to a liquid material supplying part 33a. In the present embodiment, explanation will be given, as a representative example, with respect to a case where the pipe 101 is connected to the first liquid material accommodation part 33a. The same explanation can be applied to the case where the pipe 101 is connected to the second liquid material accommodation part 33b.

The downstream-side end of the pipe 101 is connected to the air vent tank 102 via an inlet 101a. Thus, the air vent tank 102 is disposed on a downstream side of the supply path of the liquid material, relative to the liquid material supply part 33 (first liquid material accommodation part 33a). The air vent tank 102 removes any gas contained in the liquid material. The air vent tank 102 is provided with a nitrogen gas pressurizing line, a depressurizing line and a drain line which are omitted from the drawing. Each of these lines is provided with an air operated valve, and can be opened or closed by the air operated valve.

The pipe 103 is connected on a downstream side of the air vent tank 102. The pipe 103 is provided with a filter 103a. The filter 103a removes foreign matters from the liquid material which passes through the pipe 103. The downstream-side end of the pipe 103 is connected to the connection switch 104. A configuration in which the filter 103a is omitted may be employed.

The connection witch 104 has a first port 104a and a second port 104b. The downstream side of the first port 104a and the second port 104b is connected to the pipe 105. The connection switch 104 is provided to be capable of switching the connection target of the pipe 105 between the first port 104a and the second port 104b. The pipe 103 is connected to the first port 104a. The second port 104 is connected to the washing liquid supply part 34 via the pipe 110. Apart from the washing liquid supply part 34, the pipe 110 may be connected to a gas supply part (not shown). In this case, an example of the gas includes a nitrogen gas.

The pipe 105 connects the connection switch 104 with the discharge pump 106. The discharge pump 106 pushes the liquid material towards the nozzle NZ side. The downstream side of the discharge pump 106 is connected to the pipe 107. The downstream-side end of the pipe 107 is connected to nozzle pipes 108 and 109.

The nozzle pipes 108 and 109 are formed to branch from the downstream-side end of the pipe 107. The nozzle pipe 108 is connected to one end of the nozzle NZ in the lengthwise direction thereof via the inlet 108a. The nozzle pipe 109 is connected to the other end of the nozzle NZ in the lengthwise direction thereof via the inlet 109a. The inlet 109a is provided with a valve which can open or close the nozzle pipe 109. The valve is provided to be switchable by the control part CONT. At the connection portion of the nozzle pipe 109 and the nozzle NZ, a manifold NZh is formed which communicates the inside of the nozzle NZ with the outside. The nozzle pipe 109 is connected to the nozzle NZ via the manifold NZh.

The pipe 111 connects the nozzle standby part 44 with the chemical pump 112. The pipe 111 is provided with an air operated valve 111a. The air operated valve 111a opens or closes the flow path of the liquid material accommodated in the nozzle standby part 44 from the pipe 111 to the chemical pump 112. The chemical pump 112 is connected to the waste liquid storing part 35 via the pipe 113. The chemical pump 112 suctions the liquid material from the pipe 111 to the pipe 113. By the suction force of the chemical pump 112, the liquid material passing through the pipe 111 flows into the pipe 113.

The recycle system 200 has a pipe 201, a chemical pump 202, a pipe 203 ad a pipe 204. The pipe 201 is provided to branch from the pipe 111 which connects the aforementioned nozzle standby part 44 and the waste liquid storing part 35. The pipe 201 is connected to the chemical pump 202 via an inlet 201a.

The chemical pump 202 suctions the liquid material from the pipe 111 to the pipe 201. By the suction force of the chemical pump 202, the liquid material passing through the pipe 111 flows into the pipe 201. The pipe 203 connects the chemical pump 202 with the air vent tank 102.

The pipe 204 is connected to the nozzle pipe 109 between the inlet 109a and the manifold NZh. The pipe 204 is connected to the pipe 203 via an air operated vent 204a. By opening or closing the air operated vent 204a, the liquid material held inside the nozzle NZ flows from the pipe nozzle 109 to the pipe 204.

In the present embodiment, a configuration is employed in which the liquid material ejected from the nozzle NZ is supplied to the air vent tank 102 via the pipe 201, the chemical pump 202 and the pipe 203. Thus, the pipe 201, the chemical pump 202 and the pipe 203 constitutes a first recovery part 205 which recovers the liquid material ejected from the nozzle NZ. Further, the pipe 204, the air operated valve 204a and the pipe 203 constitutes a second recovery part 206 which recovers the liquid material held inside the nozzle NZ.

(Vacuum Drying Part)

The vacuum drying part VD dries the liquid material coated on the substrate S. The vacuum drying part VD has a chamber 50, a base BV and gate valves V2 and V3. The vacuum drying part VD has a configuration in which the chamber 50 is mounted on the base BV placed on the floor FL.

The chamber 50 is formed in the shape of a rectangular box. Inside the chamber 50, a treatment room 50a is formed. The chamber 50 has a first opening 51 and a second opening 52. The first opening 51 and the second opening 52 communicates the treatment room 50a with the outside of the chamber 50.

The first opening 51 is formed on a −X-side face of the chamber 50. The second opening 52 is formed on a +X-side face of the chamber 50. The first opening 51 and the second opening 52 are formed to have a size which allows the substrate S to pass through. The substrate S is placed in or taken out of the chamber 50 through the first opening 51 and the second opening 52.

The treatment room 50a is provided with a substrate transporting part 55, a gas supply part 58, a gas exhaust part 59 and a heating part 53. The substrate transporting part 55 includes a plurality of rollers 57. The rollers 57 are arranged in a pair in the Y-direction, and a plurality of the pairs are arranged in the X-direction. The plurality of rollers 57 supports the substrate S which is disposed in the treatment room 50a via the first opening 51.

By rotating each of the rollers 57 clockwise or anti-clockwise around the Y-axis in a state where the substrate S is supported by the plurality of rollers 57, the substrate S supported by each of the rollers 57 is transported in an X-direction (+X-direction or −X-direction). A float transporting part (not shown) may be used to lift the substrate for transportation.

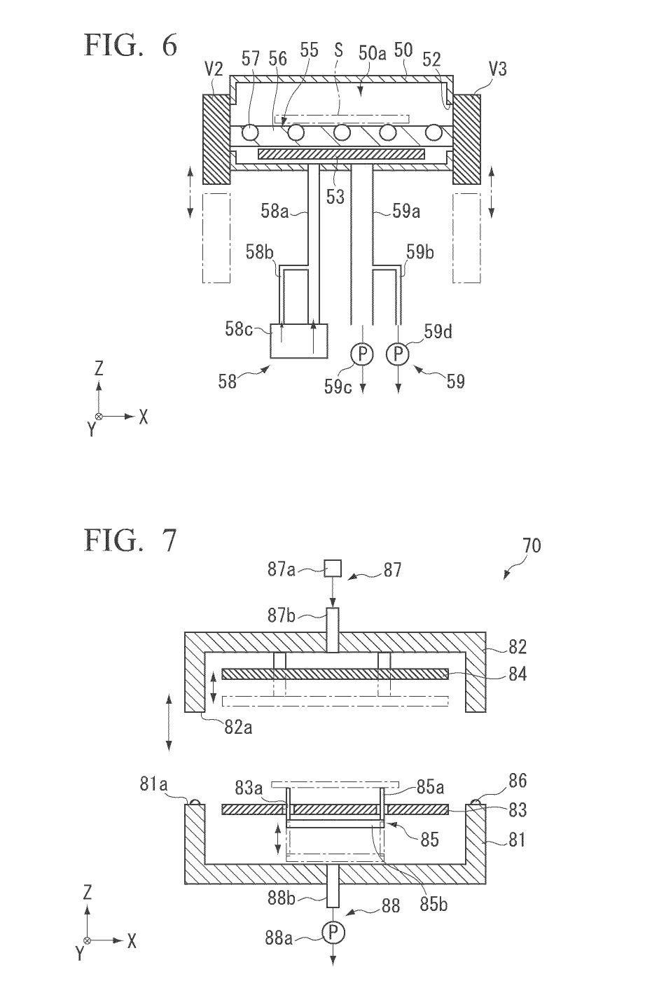

FIG. 6 is a schematic diagram showing a configuration of the vacuum drying part VD.

As shown in FIG. 6, the gas supply part 58 supplies an inert gas such as a nitrogen gas or an argon gas to the treatment room 50a. The gas supply part 58 has a first supply part 58a and a second supply part 58b. The first supply part 58a and the second supply part 58b are connected to a gas supply source 58c such as a gas bomb or a gas pipe. Supplying of a gas to the treatment room 50a is performed mainly by using the first supply part 58a. The second supply part 58b makes a fine control of the amount of gas supplied by the first supply part 58a.

The gas exhaust part 59 suctions the treatment room 50a, and discharges the gas in the treatment room 50a outside the chamber 50, thereby reducing the pressure inside the treatment room 50a. By reducing the pressure inside the treatment room 50a, evaporation of the solvent contained in the liquid material on the substrate S can be promoted, thereby drying the liquid material. The gas exhaust part 59 has a first suction part 59a and a second suction part 59b. The first suction part 59a and the second suction part 59b are connected to a suction source 59c and 59d such as a pump. Suction from the treatment room 50a is performed mainly by using the first suction part 59a. The second suction part 59b makes a fine control of the amount of suction by the first suction part 59a.

The heating part 53 heats the liquid material on the substrate S disposed in the treatment room 50a. As the heating part 53, an infrared device or a hot plate is used. The temperature of the heating part 53 can be controlled, for example, from room temperature to about 100° C. By using the heating part 53, evaporation of the solvent contained in the liquid material on the substrate S can be promoted, thereby supporting the drying treatment under reduced pressure.

(Baking Part)

The baking part BK bakes the coating film coated on the substrate S. The baking part BK includes a chamber 60 and a base BB. The baking part BK has a configuration in which the chamber 60 is mounted on the base BB placed on the floor FL.

The chamber 60 is formed in the shape of a rectangular box. Inside the chamber 60, a treatment room 60a is formed. The chamber 60 has an opening 61. The opening 61 communicates the treatment room 60a with the outside of the chamber 60. The first opening 61 is formed on a −X-side face of the chamber 60. The opening 61 is formed to have a size which allows the substrate S to pass through. The substrate S is placed in or taken out of the chamber 60 through the opening 61.

The treatment room 60a is provided with a substrate transporting part 65, a gas supply part 68, a gas exhaust part 69 and a heating part 70.

The substrate transporting part 65 has a plurality of rollers 67 and an arm part 71. The rollers 67 are arranged in a pair in the Y-direction on the substrate guide stage 66, and a plurality of the pairs are arranged in the X-direction. The plurality of rollers 67 supports the substrate S which is disposed in the treatment room 60a via the opening 61.

By rotating each of the rollers 67 clockwise or anti-clockwise around the Y-axis in a state where the substrate S is supported by the plurality of rollers 67, the substrate S supported by each of the rollers 67 is transported in an X-direction (+X-direction or −X-direction). A float transporting part (not shown) may be used to lift the substrate for transportation.

The arm part 71 is disposed on a platform 74, and transfers the substrate S between the plurality of rollers 67 and the heating part 70. The arm part 71 has a transport arm 72 and an arm actuator 73. The transport arm 72 has a substrate supporting part 72a and a moving part 72b. The substrate supporting part 72a supports the +Y-side edge and −Y-side edge of the substrate S. The moving part 72b is attached to the substrate supporting part 72a, and is movable in the X-direction and the θ Z-direction.

The arm actuator 73 actuates the moving part 72b in the X-direction or the θ Z-direction. When the moving part 72b is moved in the +X-direction by the arm actuator 73, the substrate supporting part 72a is inserted inside the heating part 70, and the substrate S is placed at a central portion of the heating part 70 as viewed in the Z-direction.

FIG. 7 is a cross-sectional view showing the configuration of the heating part 70. As shown in FIG. 7, the heating part 70 is disposed on the platform 74, and has a first accommodation part 81, a second accommodation part 82, a first heating plate 83, a second heating plate 84, a lifting part 85, a sealing part 86, a gas supply part 87 and an exhaust part 88.

The first accommodation part 81 is formed in the shape of a rectangular open box as viewed in the Z-direction, and is mounted on the bottom of the chamber 60 such that the opening faces the +Z side. The second accommodation part 82 is formed in the shape of a rectangular open box as viewed in the Z-direction, and is disposed such that the opening faces the first accommodation part 81. The second accommodation part 82 is movable in the Z direction by using a lifting mechanism (not shown). By superimposing the edge portion 82a of the second accommodation part 82 on the edge 81a of the first accommodation part 81, the inside of the first accommodation part 81 and the second accommodation part 82 is closed.

The first heating plate 83 is accommodated in the first accommodation part 81. The first heating part 83 heats a substrate S in a state where the substrate S is mounted on the first heating part 83. The first heating plate 83 is formed of, for example, quartz, a metal or the like, and is provided with a heating device such as an infrared device or a hot plate inside thereof. The temperature of the first heating plate 83 is adjustable, for example, from about 200 to 800° C. The first heating part 83 has a plurality of through-holes 83a formed thereon. The through-holes 83a allow part of the lifting part 85 to penetrate therethrough.

The second heating plate 84 is accommodated in the second accommodation part 82. The second heating plate 84 is formed of, for example, quartz or a metal material, and is provided with a heating device such as an infrared device or a hot plate inside thereof. The temperature of the second heating plate 84 is adjustable, for example, from about 200 to 800° C. The second heating plate 84 is provided to be movable independently from the second accommodation part 82 in the Z direction by a lifting mechanism (not shown). By moving the second heating plate 84 in the Z direction, the interval between the second heating plate 84 and the substrate S can be adjusted.

The lifting part 85 moves the substrate S between the arm part 71 and the first heating plate 83. The lifting part 85 has a plurality of support pins 85a and a moving part 85b which is movable in the Z direction while holding the support pins 85a. For easier discrimination of the drawings, in FIG. 7, a configuration is shown in which two support pins 85a are provided. However, in practice, it is possible to provide, for example, sixteen support pins 85a (see FIG. 7). The plurality of through-holes 83a provided on the first heating plate 83 are arranged at positions corresponding to the plurality of support pins 85a as viewed in the Z direction.

The sealing part 86 is formed on the edge portion 81a of the first accommodation part 81. As the sealing part 86, for example, an O-ring formed by a resin material or the like or a sealing material can be used. The sealing part 86 seals the first accommodation part 81 and the second accommodation part 82 in a state where the edge portion 82a of the second accommodation part 82 is superimposed on the first edge 81a of the first accommodation part 81. In this manner, the inside of the first accommodation part 81 and the second accommodation part 82 can be closed.

The gas supply part 87 supplies a nitrogen gas or the like to the treatment room 60a. The gas supply part 87 is connected to the +Z-side face of the chamber 60. The gas supply part 87 has a gas supply source 87a such as a gas bomb or a gas pipe, and a connection pipe 87b which connects the gas supply source 87a with the chamber 60.

The exhaust part 88 suctions the treatment room 60a, and discharges the gas in the treatment room 80a outside the chamber 60. The exhaust part 88 is connected to the −Z-side face of the chamber 60. The exhaust part 88 has a suction source 88a such as a pump, and a connection pipe 88b which connects the suction source 88a with the chamber 60.

Further, in the present embodiment, solvent concentration sensors SR3 and SR4 are provided. Like the aforementioned solvent concentration sensors SR1 and SR2, the solvent concentration sensors SR3 and SR4 detects the concentration of the solvent (in the present embodiment, hydrazine) for the liquid material in the ambient atmosphere, and sends the detection results to the control part CONT. The solvent concentration sensor SR3 is provided on the platform 74 on the +Y side of the heating part 70 within the treatment room 60a. The solvent concentration sensor SR3 is provided at a position remote from the heating part 70. The solvent concentration sensor SR4 is provided outside the chamber 60. In the present embodiment, for detecting the concentration of hydrazine which has a larger specific gravity than air, like the solvent concentration sensors SR1 and SR2, the solvent concentration sensors SR3 and SR4 are disposed on the lower side of the transport path of the substrate S in the vertical direction. Further, by providing a solvent concentration sensor SR4 outside the chamber 60, it becomes possible to detect leakage of hydrazine from the chamber 60.

(Substrate Transport Path)

The second opening 12 of the substrate loading/unloading part LU, the first opening 21 and the second opening 22 of the coating part CT, the first opening 51 and the second opening 52 of the vacuum drying part VD and the opening 61 of the baking part BK are provided along a line in parallel to the X-direction. Thus, the substrate S is moved along a line in the X-direction. Further, in the path from the substrate loading/unloading part LU to the heating part 70 of the baking part BK, the position in the Z-direction is maintained. Thus, stirring of the gas around the substrate S can be suppressed.

(Anti-Chamber)

As shown in FIG. 1, the chamber 20 has anti-chambers AL1 to AL3 connected thereto.

The anti-chambers AL1 to AL3 are provided to communicate with the inside and outside of the chamber 20. Each of the anti-chambers AL1 to AL3 is a path through which a component of the treatment room 20a is taken out of the chamber 20 or the component is placed into the treatment room 20a from outside the chamber 20.

The anti-chamber AL1 is connected to the ejection part 31. The nozzle NZ provided in the ejection part 31 can be taken out of or placed into the treatment room 20a via the anti-chamber AL1. The anti-chamber AL2 is connected to the liquid material supply part 33. The liquid material supply part 33 can be taken out of or placed into the treatment room 20a via the anti-chamber AL2.

The anti-chamber AL3 is connected to a liquid material preparation part 36. In the liquid material preparation part 36, a liquid can be taken out of or placed into the treatment room 20a via the anti-chamber AL3. The anti-chamber AL3 is formed to have a size which allows the substrate S to pass through. Therefore, for example, when a test coating of the liquid material is to be conducted in the coating part CT, a substrate S prior to treatment can be supplied to the treatment room 20a from the anti-chamber AL3. Further, the substrate S after the test coating can be taken out from the anti-chamber AL3. Moreover, the substrate S can be taken out from the anti-chamber AL3 temporarily in emergency.

The chamber 60 has an anti-chamber AL4 connected thereto.

The anti-chamber AL4 is connected to the heating part 70. The anti-chamber AL4 is formed to have a size which allows the substrate S to pass through. Therefore, for example, when heating of the substrate S is to be conducted in the heating part 70, the substrate S can be supplied to the treatment room 60a from the anti-chamber AL4. Further, the substrate S after the heat treatment can be taken out from the anti-chamber AL4.

(Glove Part)

As shown in FIG. 1, the chamber 20 has a glove part GX1 connected thereto. Further, the chamber 60 has a glove part GX2 connected thereto.

The glove parts GX1 and GX2 are parts where an operator accesses the inside of the chamber 20 and the chamber 60. By inserting the hands inside the glove parts GX1 and GX2, the operator can conduct maintenance inside the chamber 20 and the chamber 60. The glove parts GX1 and GX2 are formed to have a bag-like shape. The glove parts GX1 and GX2 are respectively provided at a plurality of portions on the chamber 20 and the chamber 60. A sensor may be provided inside the chamber 20 and the chamber 60 which detects whether or not an operator has put his hand in the glove part GX1 or GX2.

(Gate Valve)

Between the second opening 12 of the substrate loading/unloading part LU and the first opening 21 of the coating part CT, a gate valve V1 is provided. The gate valve V1 is provided to be movable in the Z-direction by an actuator (not shown). By moving the gate valve V1 in the Z-direction, the second opening 12 of the substrate loading/unloading part LU and the first opening 21 of the coating part CT are simultaneously opened or closed. When the second opening 12 and the first opening 21 are simultaneously opened, a substrate S can be moved through the second opening 12 and the first opening 21.

Between the second opening 22 of the coating part CT and the first opening 51 of the vacuum drying part VD, a gate valve V2 is provided. The gate valve V2 is provided to be movable in the Z-direction by an actuator (not shown). By moving the gate valve V2 in the Z-direction, the second opening 22 of the coating part CT and the first opening 51 of the vacuum drying part VD are simultaneously opened or closed. When the second opening 22 and the first opening 51 are simultaneously opened, a substrate S can be moved through the second opening 22 and the first opening 51.

Between the second opening 52 of the vacuum drying part VD and the opening 61 of the baking part BK, a gate valve V3 is provided. The gate valve V3 is provided to be movable in the Z-direction by an actuator (not shown). By moving the gate valve V3 in the Z-direction, the second opening 52 of the vacuum drying part VD and the opening 61 of the baking part BK are simultaneously opened or closed. When the second opening 52 and the opening 61 are simultaneously opened, a substrate S can be moved through the second opening 52 and the opening 61.

(Control Device)

The control part CONT is a part which has the overall control of the coating apparatus CTR. Specifically, the control part CONT controls the operations of the substrate loading/unloading part LU, the coating part CT, the vacuum drying part VD, the baking part BK and the gate valves V1 to V3. Further, the control part CONT performs the supplying operation of the liquid material and the washing liquid by the supplying system 100, and the recycling operation of the liquid material by the recycling system 200. The control part CONT has a timer or the like (not shown) for measuring the treatment time.

(Coating Method)

Next, a coating method according to one embodiment of the present invention will be described. In this embodiment, a coating film is formed on the substrate S by using the coating apparatus CTR having the above-described configuration. The operations performed by the respective parts of the coating apparatus CTR are controlled by the control part CONT.

Firstly, the control part CONT loads a substrate S on the substrate loading/unloading part LU from the outside. In this case, the control part CONT closes the gate valve V1, opens the lid portion 14 and accommodates the substrate S in the accommodation room 10a of the chamber 10. After the substrate S is accommodated in the accommodation room 10a, the control part CONT closes the lid portion 14.

After the lid portion 14 is closed, the control part CONT opens the gate valve V1, so as to communicate the accommodation room 10a of the chamber 10 with the treatment room 20a of the chamber 20 of the coating part CT. After opening the gate valve V1, the control part CONT transports the substrate S in the X-direction using the substrate transporting part 15.

After a portion of the substrate S has been inserted into the treatment room 20a of the coating part CT, the control part CONT uses the substrate transporting part 25 to completely load the substrate S into the treatment room 20a. After the substrate S has been loaded, the control part CONT closes the gate valve V1. After closing the gate valve V1, the control part CONT transports the substrate S to the treatment stage 28.

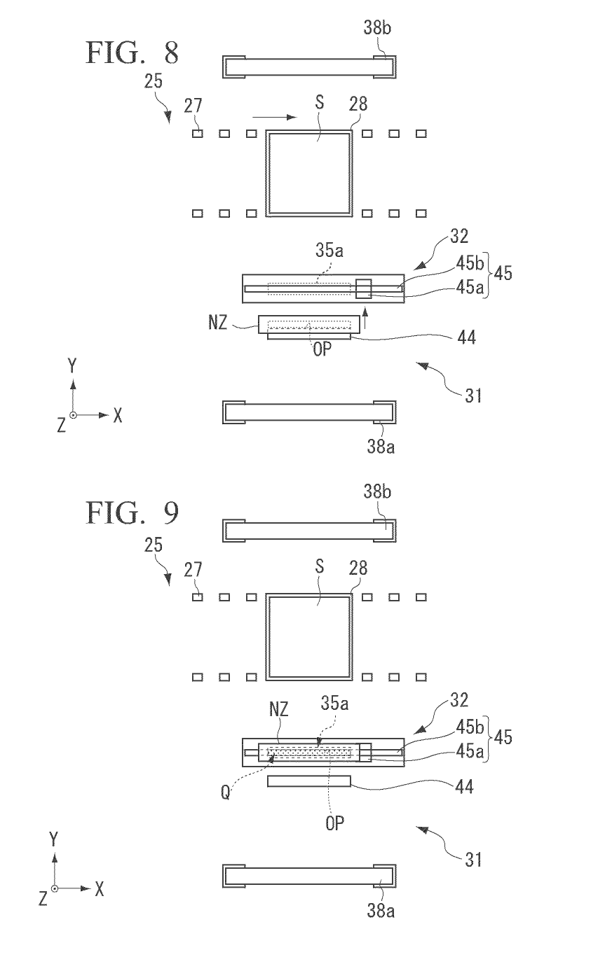

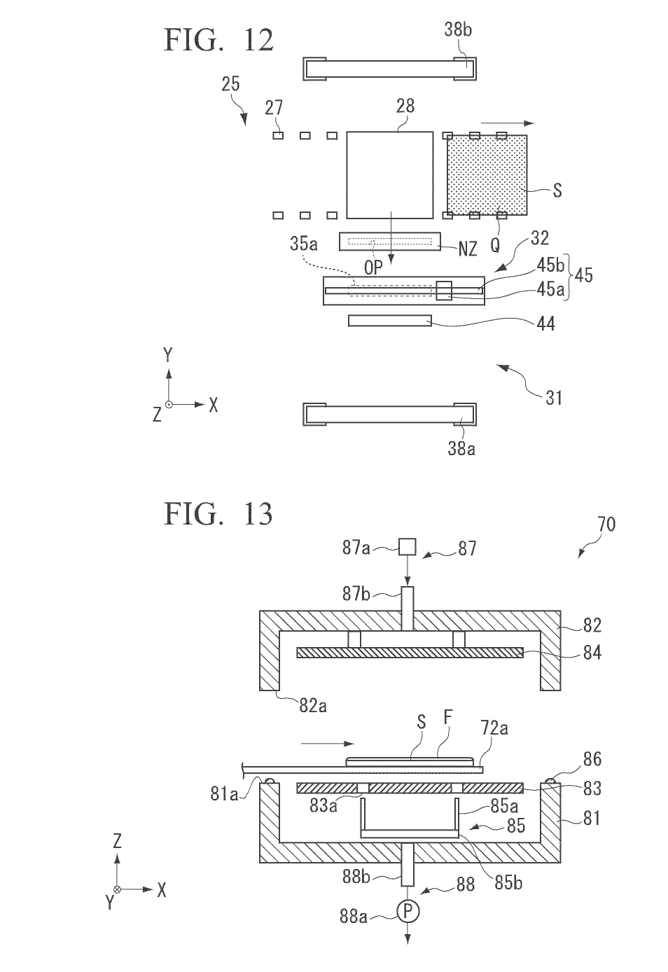

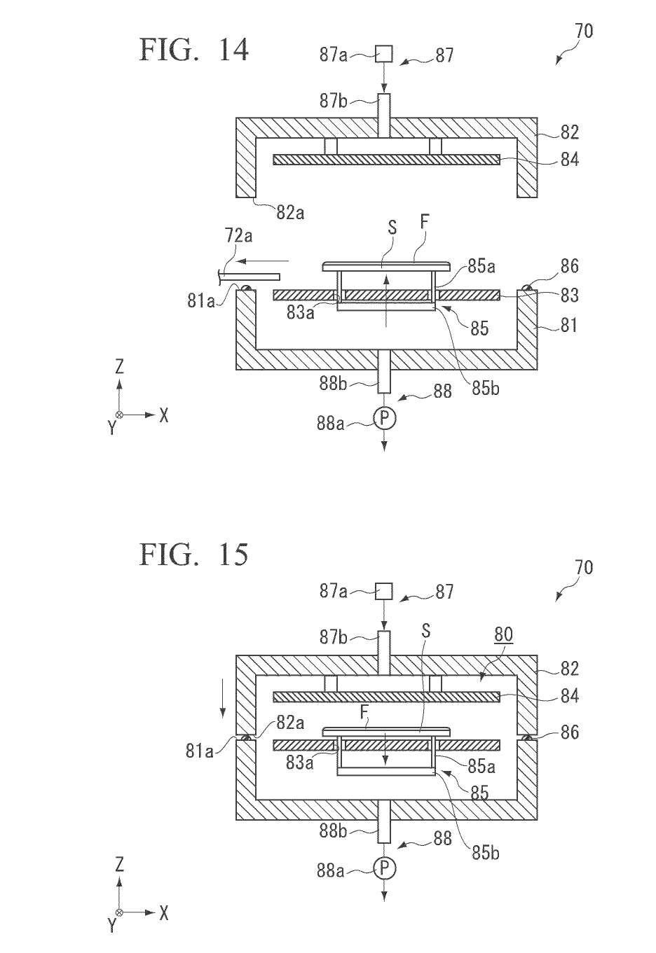

FIG. 8 is a diagram showing a simplified configuration of the coating part CT in which part of the components have been abbreviated. Herebelow, the same applies to FIG. 9 to FIG. 12. As shown in FIG. 8, when the substrate S is mounted on the treatment stage 28, a coating treatment is conducted by the coating part CT. Prior to the coating treatment, the control part CONT closes the gate valves V1 and V2, and conducts supplying and suctioning of an inert gas using the gas supplying part 37a and the gas exhaust part 37b.

By this operation, the atmosphere and the pressure of the treatment room 20a can be adjusted. After adjusting the atmosphere and the pressure of the treatment room 20a, the control part CONT uses the nozzle actuator NA (not shown in FIG. 8) to move the nozzle NZ from the nozzle standby part 44 to the nozzle-tip control part 45. Thereafter, during the coating treatment, the control part CONT continuously conducts the adjusting operation of the atmosphere and the pressure of the treatment room 20a.

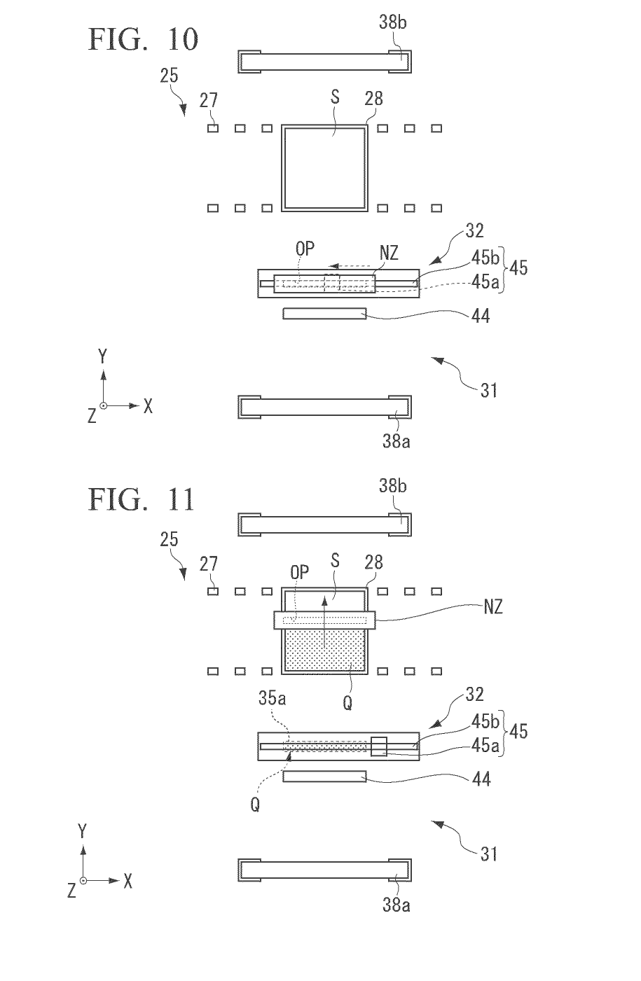

When the nozzle NZ reaches the nozzle-tip control part 45, as shown in FIG. 9, the control part CONT conducts a preliminary ejection operation of the nozzle NZ. In the preliminary ejection operation, the control part CONT ejects the liquid material Q from the ejection opening OP. After the preliminary ejection operation, as shown in FIG. 10, the control part CONT moves the wiping part 45a along the guide rail 45b in the X-direction, so as to wipe the tip TP of the nozzle NZ and the inclined part in the vicinity thereof.

After wiping the tip TP of the nozzle NZ, the control part CONT moves the nozzle NZ to the treatment stage 28. After the ejection opening OP of the nozzle NZ reaches the −Y-side end of the substrate S, as shown in FIG. 11, the control part CONT ejects the liquid material Q from the ejection opening OP to the substrate S while moving the nozzle NZ in the +Y-direction at a predetermined speed. By this operation, a coating film of the liquid material Q is formed on the substrate S.

After forming a coating film of the liquid material Q on a predetermined region of the substrate S, the control part CONT uses the substrate transporting part 25 to move the substrate S from the treatment stage 28 to the second stage 26B in the +X-direction. Further, the control part CONT moves the nozzle NZ in the −Y-direction, and returns the nozzle NZ to the nozzle standby part 44.

After the substrate S reaches the second opening 22 of the chamber 20, the control part CONT opens the gate valve V2, and transports the substrate S from the coating part CT to the vacuum drying part VD. After the substrate S is accommodated in the treatment room 50a of the chamber 50 provided in the vacuum drying part VD, the control part CONT closes the gate valve V2, and performs a vacuum drying treatment of the substrate S in the treatment room 50a. After the vacuum drying treatment, the control part CONT uses the gas supply part 58 to adjust the atmosphere inside the treatment room 50a and uses the gas exhaust part 59 to reduce the pressure inside the treatment room 50a. When the pressure inside the treatment room 50a is reduced by this operation, evaporation of the solvent contained in the coating film of the liquid material Q formed on the substrate S is promoted, and the coating film is dried. The control part CONT may use the heating part 53, so as to promote evaporation of the solvent contained in the liquid material on the substrate S, thereby supporting the vacuum drying treatment. By this treatment, a coating film F is formed on the substrate S (see FIG. 13).

After the vacuum drying treatment, the control part CONT opens the gate valve V3, and transports the substrate S from the vacuum drying part VD to the baking part BK. After the substrate S is accommodated in the treatment room 60a of the chamber 60 provided in the baking part BK, the control part CONT closes the gate valve V3.

After the substrate S has been disposed at a central portion above the first heating plate 83 by the movement of the substrate supporting part 72a, the control part CONT moves the lifting part 85 in the +Z direction. By this operation, the substrate S leaves the substrate supporting part 72a of the transport arm 72, and is supported by the plurality of support pins 85a of the lifting part 85. In this manner, the substrate S is delivered from the substrate supporting part 72a to the lifting part 85. After the substrate S has been supported by the support pins 85a of the lifting part 85, the control part CONT withdraws the substrate supporting part 72a outside the heating part 70 in the −X direction.

After withdrawing the substrate supporting part 72a, as shown in FIG. 15, the control part CONT moves the lifting part 85 in the −Z direction, and also moves the second accommodation part 82 in the −Z direction. By this operation, the edge portion 82a of the second accommodation part 82 is superimposed on the edge 81a of the first accommodation part 81, so that the sealing part 86 is sandwiched between the edge portion 82a and the edge portion 81a. As a result, a closed baking room 80 is formed by the first accommodation part 81, the second accommodation part 82 and the sealing part 86.

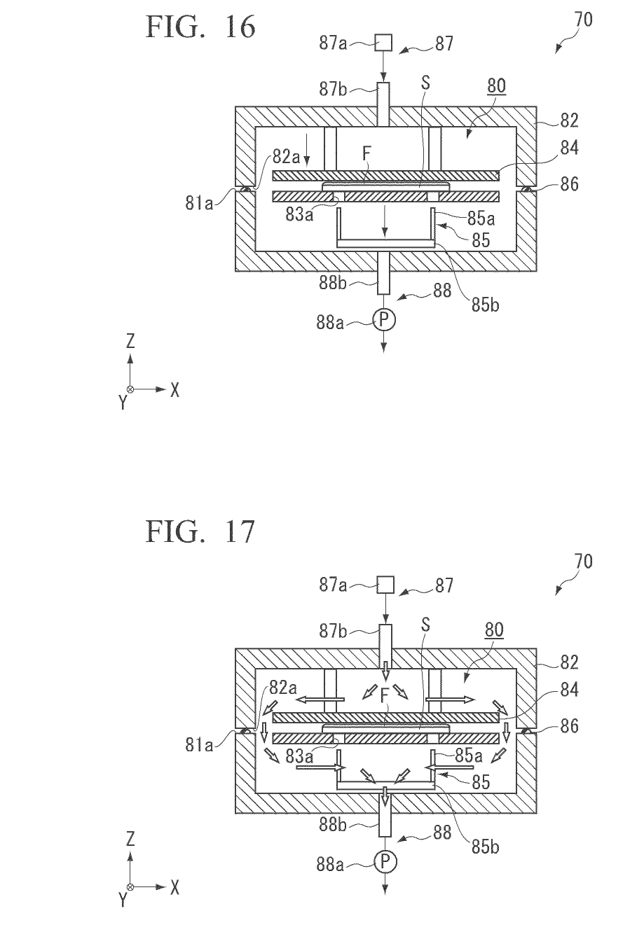

After forming the baking room 80, as shown in FIG. 16, the control part CONT moves the lifting part 85 in the −Z direction and mounts the substrate S on the first heating plate 83. After the substrate S has been mounted on the first heating plate 83, the control part CONT moves the second heating plate 84 in the −Z direction, so that the second heating plate 84 approaches the substrate S. The control part CONT appropriately adjusts the position of the second heating plate in the Z direction.

After adjusting the position of the second heating plate 84 in the Z direction, as shown in FIG. 17, a hydrogen sulfide gas is supplied to the baking room by using the gas supply part 87, and the baking room is suctioned by using the exhaust part 88. By this operation, not only the atmosphere and pressure inside the baking room 80 are adjusted, but also a stream of the hydrogen sulfide gas is formed from the second accommodation part 82 to the first accommodation part 81. In a state where the stream of the hydrogen sulfide gas is formed, the control part CONT actuates the first heating plate 83 and the second heating plate 84, so as to perform the baking operation of the substrate S. By this operation, the solvent component evaporated from the coating film F and the like are swept away by the stream, and suctioned by the exhaust part 88.

After the baking operation has been completed, the control part CONT transports the substrate S in the −X direction. Specifically, the substrate S is unloaded from the baking part BK via the heating part 70, the arm part 71 and the substrate guide stage 66, and is returned to the substrate loading/unloading part LU via the coating part CT. After the substrate S has been returned to the substrate loading/unloading part LU, the control part CONT opens the lid portion 14 in a state where the gate valve V1 is closed. Thereafter, an operator collects the substrate S in the chamber 10, and accommodates a new substrate S in the accommodation room 10a of the chamber 10.

In the case where, after the substrate S has been returned to the substrate loading/unloading part LU, another coating film is formed to be superimposed on the coating film F formed on the substrate S, the control part CONT transports the substrate S to the coating part CT again, and repeats the coating treatment, the vacuum drying treatment and the baking treatment. In this manner, a coating film F is formed on the substrate S.

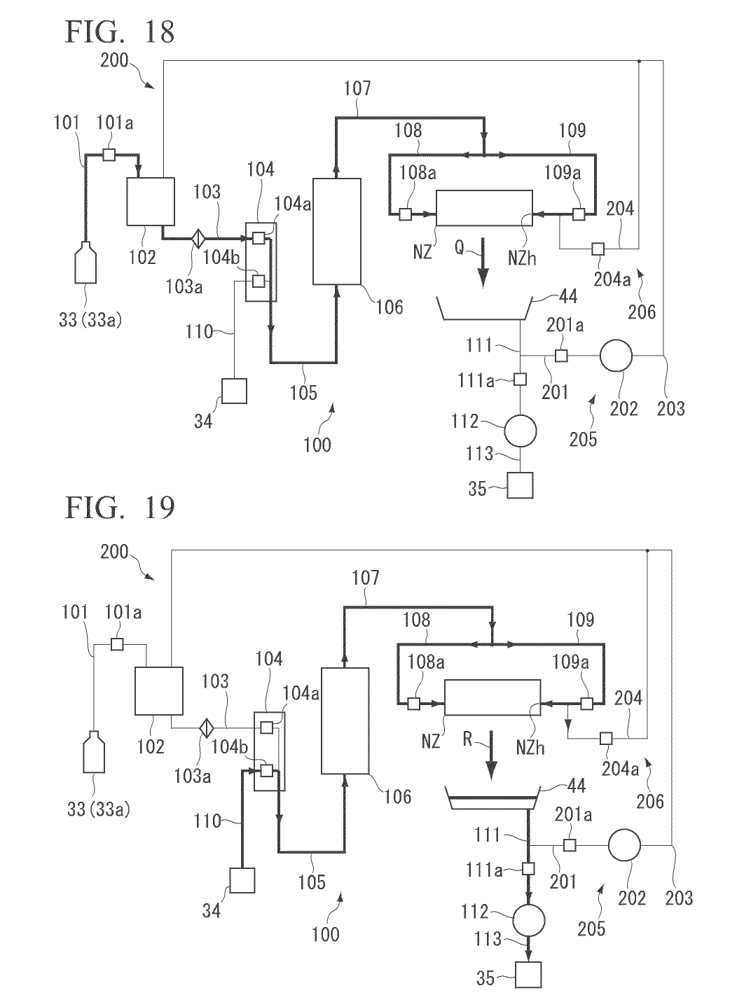

With respect to the sequence of operations, the operation of the coating part CT will be explained using piping drawings. FIG. 18 to FIG. 21 are piping diagrams showing a flow path configuration of the coating part CT.

Firstly, a case where the liquid material Q is ejected from the nozzle NZ to the substrate S will be explained. In such a case, the control part CONT connects the first port 104a with the pipe 105 in advance. In this state, as shown in FIG. 18, the control part CONT applies pressure to the first liquid material accommodation part 33a, so as to discharge the liquid material contained in the first liquid material accommodation part 33a. By this operation, the liquid material flows into the air vent tank 102 via the pipe 101 and the inlet 101a.

The control part CONT uses the air vent tank 102 to remove any gas from the liquid material. Thereafter, the control part CONT discharges the liquid material to the pipe 103 on the downstream side of the air vent tank 102. The liquid material which flows through the pipe 103 reaches the first port 104a of the connection switch 104 in a state where foreign matters have been removed by the filter 103a.

Since the first port 104a is connected to the pipe 105 in advance by the control part CONT, the liquid material which reaches the first port 104a flows into the pipe 105 via the first port 104a. The liquid material which has flowed into the pipe 105 reaches the discharge pump 106.

After the liquid material has reached the discharge pump 106, the control part CONT actuates the discharge pump 106, and discharges the liquid material to the pipe 107. The liquid material discharged to the pipe 107 diverges and flows into the nozzle pipe 108 and the nozzle pipe 109, and flows into the inside of the nozzle NZ via the inlet 108a and the inlet 109a. The liquid material which passes through the nozzle pipe 109 flows into the inside of the nozzle NZ via the manifold NZh.

Thereafter, the control part CONT adjusts the pressure of the discharge pump 106, so as to eject the liquid material Q from the nozzle NZ. The ejected liquid material Q is disposed, for example, on a substrate S, and a coating film is formed.

Next, a case where the supply system 100 and the nozzle NZ are washed with a washing liquid will be described. In such a case, the control part CONT connects the first port 104b with the pipe 105 in advance. Further, the control part CONT disposes the nozzle NZ on the +Z side of the nozzle standby part 44 in a state where the tip of the nozzle faces the discharge part of the nozzle standby part 44.

In this state, as shown in FIG. 19, the control part CONT applies pressure to the washing liquid supply part 34, so as to discharge the washing liquid from the washing liquid supply part 34 to the pipe 110. The washing liquid discharged to the pipe 110 reaches the second port 104b of the connection switch 104. Since the second port 104b is connected to the pipe 105 in advance by the control part CONT, the washing liquid which reaches the second port 104b flows into the pipe 105 and the discharge pump 106 via the second port 104b.

The washing liquid which has flowed into the pipe 105 reaches the discharge pump 106. After the washing liquid has reached the discharge pump 106, the control part CONT actuates the discharge pump 106, and discharges the washing liquid to the pipe 107. The washing liquid discharged to the pipe 107 diverges and flows into the nozzle pipe 108 and the nozzle pipe 109, and flows into the inside of the nozzle NZ via the inlet 108a and the inlet 109a. The washing liquid which passes through the nozzle pipe 109 flows into the inside of the nozzle NZ via the manifold NZh.

Thereafter, the control part CONT adjusts the pressure of the discharge pump 106, so as to eject the washing liquid R from the nozzle NZ. The ejected washing liquid R is accommodated in the discharge part of the nozzle standby part 44 disposed on the −Z side of the nozzle NZ. The control part CONT opens the air operated valve 111a, and actuates the chemical pump 112, so as to suction the washing liquid R accommodated in the discharge part of the nozzle standby part 44 to the waste liquid storing part 35.

By the above operations, the washing liquid is supplied to the inside of the nozzle NZ via the pipe 105, the discharge pump 106, the pipe 107, the nozzle pipes 108 and 109. As a result, these paths and the inside of the nozzle NZ can be washed. The waste water after the washing (a mixture of the liquid material, washing liquid and the like) is collected in the waste liquid storing part 35 via the pipe 111.

After the washing operation with the washing liquid, the control part CONT may ventilate the inside of the nozzle NZ. In such a case, a gas supply part (not shown) is connected to the supplying system 100, and the manifold NZh is opened to the outside in a state where a gas is supplied to the supplying system 100. By this operation, the gas inside the nozzle NZ can be ejected outside, so as to discharge foreign matters inside the nozzle NZ.

In the case of supplying a liquid material to the nozzle NZ in the above operation, when the liquid material is retained between the liquid material supply part 33 and the nozzle NZ, there is a possibility that fluctuation occurs in the concentration of the components of the liquid material. When the liquid material is coated on the substrate S in a state where the there is fluctuation in the concentration of the components, there is a possibility that the film property of the coating film F formed on the substrate S varies.

Therefore, in the present embodiment, for preventing variation in the film property of the coating film, the control part CONT conducts an operation (recycling step) in which the liquid material is recovered from at least one of the supplying system 100 and the nozzle NZ, and the recovered liquid material is supplied to at least one of the supplying system 100 and the nozzle NZ.

Herebelow, the recycling step will be explained. As an example of the recycling step, an operation in which the liquid material Q ejected from the nozzle NZ is recovered will be explained (first recovering step). In such a case, the control part CONT connects the first port 104a with the pipe 105 in advance. Further, the control part CONT disposes the nozzle NZ on the +Z side of the nozzle standby part 44 in a state where the tip of the nozzle faces the nozzle standby part 44. In this state, the control part CONT conducts the same control operation as in the case of ejecting a liquid material to the substrate S, thereby ejecting the liquid material Q from the nozzle NZ. The ejected liquid material Q is accommodated in the discharge part of the nozzle standby part 44 disposed on the −Z side of the nozzle NZ.

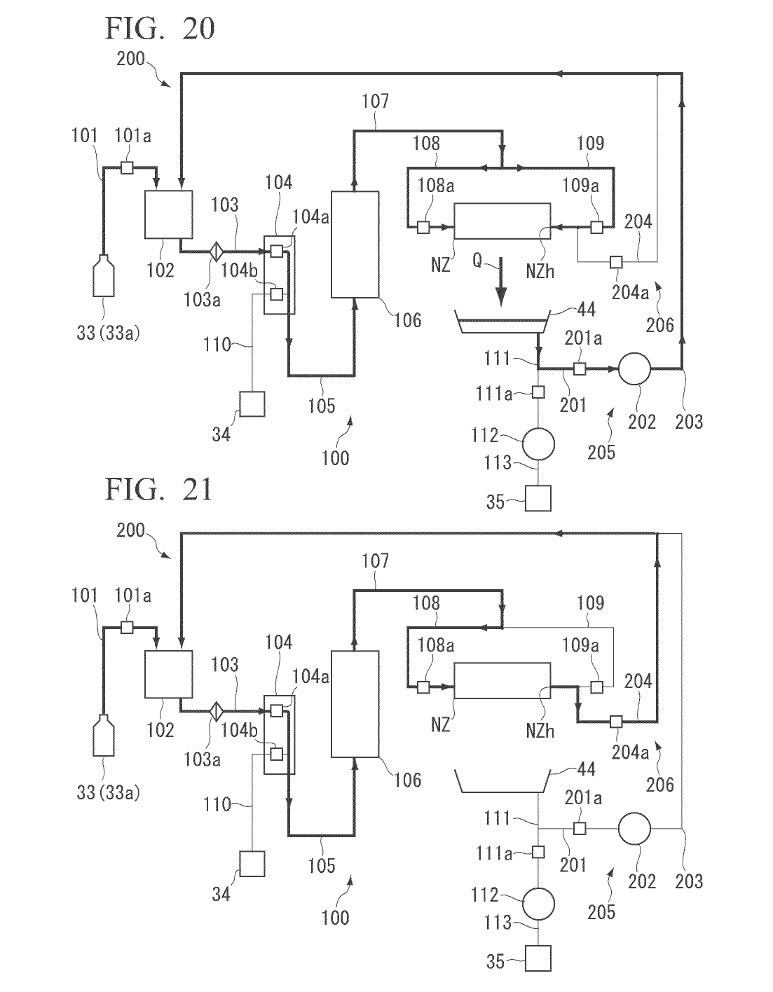

In this state, as shown in FIG. 20, the control part CONT actuates the chemical pump 202. In this case, by the suction power of the chemical pump 202, the liquid material Q accommodated in the discharge part of the nozzle standby part 44 flows into the pipe 201 via the pipe 111. Thereafter, the control part CONT controls the suction power of the chemical pump 202, so that the liquid material Q flown into the pipe 201 flows into the chemical pump 202 and the pipe 203 via the inlet 201a, and returned to the air vent tank 102.

Next, as another example of the recycling step, an operation in which the liquid material Q held inside the nozzle NZ is recovered (second recovering step) will be explained. In such a case, the control part CONT connects the first port 104a with the pipe 105 in advance. In this state, the control part CONT conducts the same control operation as in the case of ejecting a liquid material to the substrate S, thereby holding the liquid material Q inside the nozzle NZ.

In this state, as shown in FIG. 21, the control part CONT opens the valve of the inlet 109a provided on the nozzle pipe 109, and opens the air operated valve 204a. Thereafter, the control part CONT actuates the discharge pump 106, so as to discharge the liquid material held inside the nozzle NZ to the nozzle pipe 109 and the pipe 204 via the air operated valve 204a. By this operation, the liquid material flows from the nozzle pipe 108-side to the nozzle pipe 109-side inside the nozzle NZ, and flows into the pipe 204.

Thereafter, the control part CONT controls the discharge power of the discharge pump 106, so that the liquid material flown into the pipe 204 merges with the pipe 203, and is returned to the air vent tank 102 via the pipe 203.

As described above, according to the present embodiment, by virtue of being provided with a recycling system 200 in which the liquid material Q is recovered from the nozzle NZ, and the recovered liquid material Q is supplied to the supplying system 100, the liquid material Q can be prevented from being retained between the supplying system 100 and the nozzle NZ. As a result, the concentration of the components contained in the liquid material Q can be prevented from being changed, thereby preventing variation in the film properties of the coating film F.

The technical scope of the present invention is not limited to the above-described embodiment, but may be appropriately modified into various forms without departing from the spirit of the present invention.

For example, in the aforementioned embodiment, the air vent tank 102 may have a configuration in which a pressure reducing line and an air operable valve (not shown) are provided. By such a configuration, the inside of the tank can be easily degassed.

Alternatively, a configuration in which the air vent tank 102 is provided with a liquid material amount detection part (not shown) may be employed. The liquid material amount detection part detects whether or not the liquid material accommodated in the tank has filled the tank. When the liquid material is accommodated in the tank to fill the tank, a new liquid material can be controlled not to be collected in the tank.

Alternatively, a configuration in which the air vent tank 102 is provided with a detection device such as a viscosity detection part (not shown) may be employed. By detecting the viscosity, it can be determined whether or not the liquid material accommodated in the air vent tank 102 can be used in terms of viscosity. When it is determined that the liquid material cannot be used, the liquid material can be discharged from the drain line in the aforementioned embodiment.

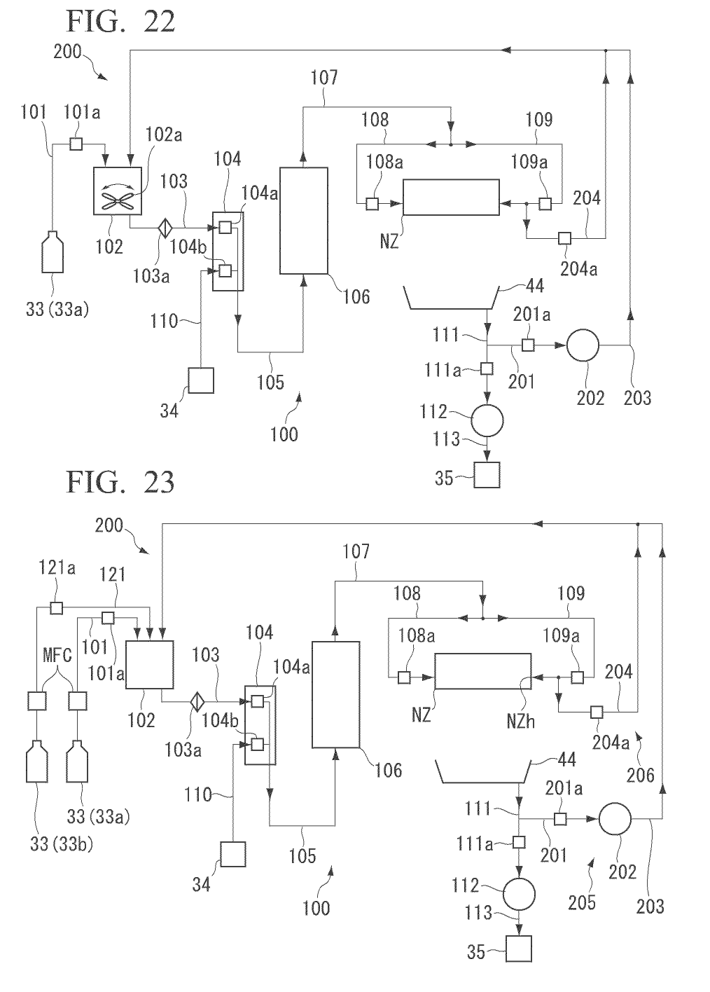

Further, in the aforementioned embodiment, explanation was given taking example of preventing the retention of the liquid material Q by recycling the liquid material Q using the recycling system 200. However, the present invention is not limited thereto. For example, as shown in FIG. 22, a configuration in which a stirring mechanism 102a is provided inside the air vent tank 102 may be employed. In such a configuration, by stirring the liquid material Q inside the air vent tank 102 using the stirring mechanism 102a (stirring step), the liquid material inside the air vent tank 102 can be maintained in a flowing state, thereby efficiently preventing retention of the liquid material Q together with the recycling step by the recycling system 200. Further, a configuration in which the liquid supply part 33 (first liquid accommodation part 33a) is provided with a stirring mechanism may be employed.

In the aforementioned embodiment, explanation was given taking example of a single path from the liquid material supply part 33 of the supplying system 100 to the air vent tank 102. However, the present invention is not limited thereto. Herebelow, the case where there are a plurality of paths from the liquid material supply part 33 to the air vent tank 102 will be explained.

As shown in FIG. 23, as the liquid material supply part 33 of the supplying system 100, a second liquid accommodation part 33b is used in addition to the first liquid accommodation part 33a. The second liquid accommodation part 33b is connected to the air vent tank 102 via a pipe 121. Thus, a first liquid material from the first liquid material accommodation part 33a and a second liquid material from the second liquid material accommodation part 33b are mixed together in the air vent tank 102. A configuration in which a stirring mechanism (not shown) for stirring the first liquid material and the second liquid material is provided inside the air vent tank 102 may be employed. Further, a configuration in which a sensor for detecting the liquid material component after stirring is provided inside the air vent tank 102 may be employed.

Each of the pipe 101 and the pipe 121 is provided with a liquid flow control part MFC which controls the flow of the liquid. Each liquid flow control part MFC controls the flow of the first liquid material which passes through the pipe 101 and the flow of the second liquid material which passes through the pipe 121. By this configuration, it becomes possible to avoid the state where the first liquid material and the second liquid material are separated in the liquid material supply part 33.

In the aforementioned embodiment, explanation was given taking example of a configuration in which the liquid material recovered by the recycling system 200 is returned to the air vent tank 102. However, the present invention is not limited thereto. For example, as shown in FIG. 24, a configuration in which the pipe 203 is connected to the liquid material supply part 33 (first liquid material supply part 33a) may be employed. In such a case, the liquid material recovered by the recycling system 200 is returned to the liquid material supply part 33 (first liquid material supply part 33a). Alternatively, a configuration in which the pipe 203 is connected to the nozzle NZ may be employed (such a configuration is not shown in the figures). In such a case, the liquid material recovered by the recycling system 200 is returned to the nozzle NZ.

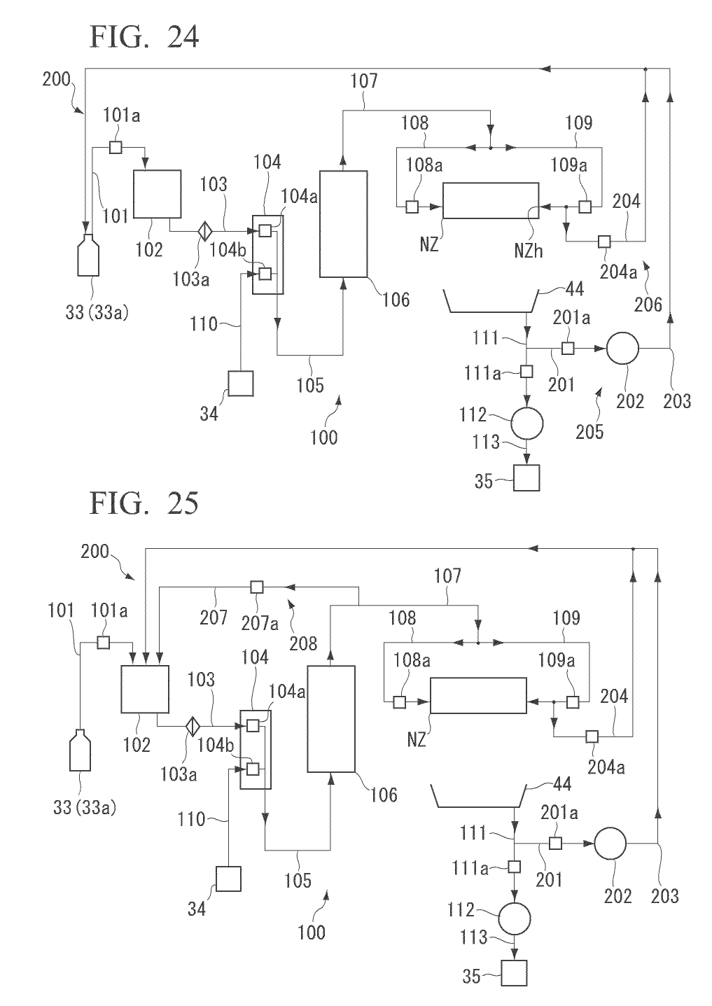

In the aforementioned embodiment, explanation was given taking example of recovering the liquid material ejected from the nozzle NZ and the liquid material held inside the nozzle NZ, i.e., a configuration in which the liquid material Q via the nozzle NZ is recovered and recycled. However, the present invention is not limited thereto. For example, as shown in FIG. 25, a configuration in which a pipe 207 is connected to a part of the supply system 100 (the pipe 107 in the example shown in FIG. 25) may be employed.

The pipe 207 is connected to the air vent tank 102 via an air operated valve 207a. The control part CONT actuates the air operated valve 207a to allow the liquid material Q within the pipe 107 to flow into the pipe 207 (third recovering step). As such, the pipe 207 and the air operated valve 207a constitutes a third recovery part 208.

In the example shown in FIG. 25, the pipe 207 is connected to the air vent tank 102. However, the pipe 207 may be connected to the liquid material supply part 33 (first liquid material supply part 33a). As such, a configuration in which the liquid material Q in the supplying system 100 is recovered and recycled may be employed. Alternatively, the pipe 207 may be connected to the nozzle NZ.

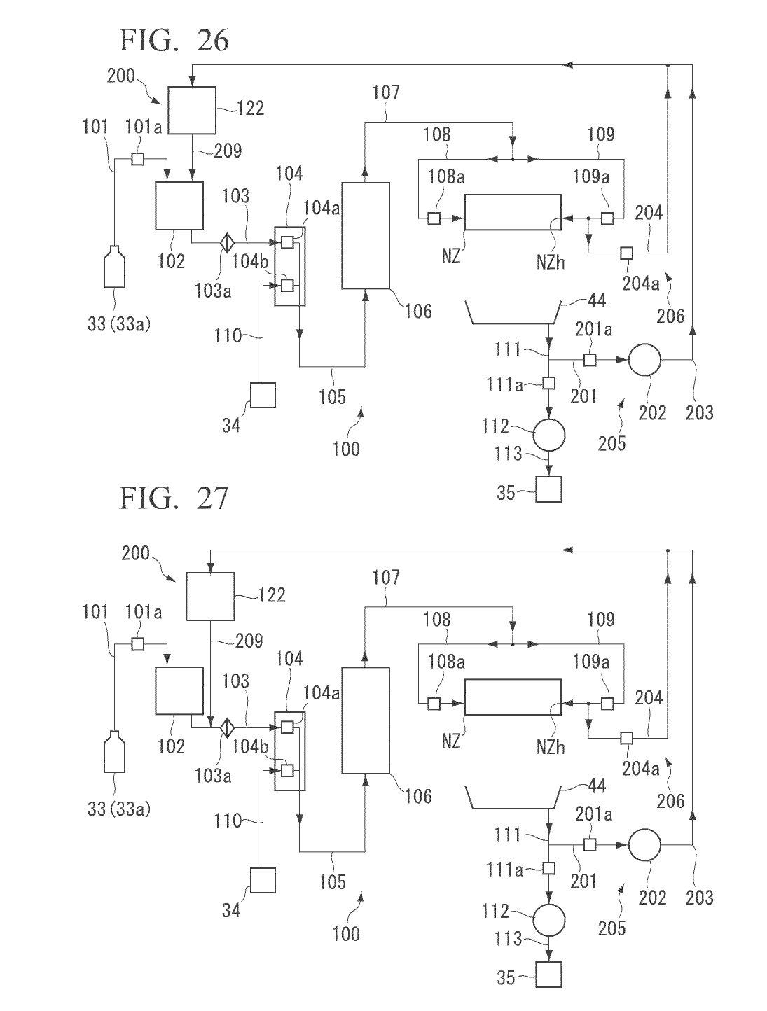

In the aforementioned embodiment, explanation was given taking example of a configuration in which the pipe 203 of the recycling system 200 is directly recycled to the air vent tank 102. However, the present invention is not limited thereto. For example, as shown in FIG. 26 and FIG. 27, a configuration in which a recovery tank 122 is separately provided in addition to the air vent tank 102 may be employed.

In the configuration shown in FIG. 26, the pipe 203 of the recycling system 200 is connected to the recovery tank 122. Further, the recovery tank 122 is connected to the air vent tank 102 via a pipe 209. As such, the liquid material firstly flows from the pipe 203 into the recovery tank 203, and after being accommodated in the recovery tank 122, the liquid material is supplied to the air vent tank 102.

In the configuration shown in FIG. 26, the pipe 203 of the recycling system is connected to the recovery tank 122. Further, the recovery tank 122 is connected to the pipe 103 via a pipe 209. As such, the liquid material flows from the pipe 203 into the recovery tank 203, and after being accommodated in the recovery tank 122, the liquid material is supplied to the pipe 103.

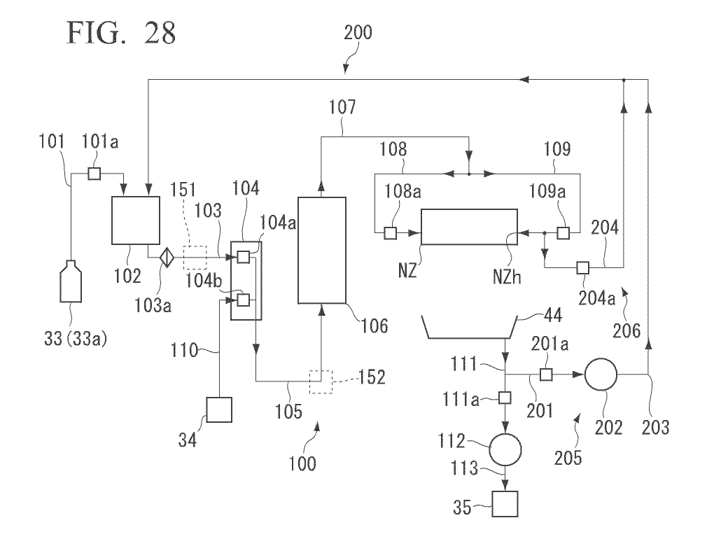

In addition to the configuration of the aforementioned embodiment, for example, as shown in FIG. 28, a degassing mechanism may be provided on a downstream side of the air vent tank 102. In such a case, for example, a degassing mechanism 151 may be provided on the pipe 103. Further, a degassing mechanism 152 may be provided on the pipe 105. With respect to the degassing mechanisms 151 and 152, either one may be provided, or both may be provided. The degassing mechanism 151 and the degassing mechanism 152 have the same configuration. As such, in a configuration in which the liquid material is stored in the air vent tank 102 (i.e., a configuration in which the air vent tank 102 serves as the storing part), the liquid material can be subjected to a degassing treatment on a downstream side of the discharge direction of the liquid material, relative to the air vent tank 102

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A coating apparatus comprising:
a coating part comprising a nozzle which ejects a liquid material containing an oxidizable metal and a solvent to a substrate;
a supplying system which supplies the liquid material to the coating part; and
a recycling system which recovers the liquid material from at least one of the supplying system and the coating part, and supplies the recovered liquid material to at least one of the supplying system and the coating part.

2. The coating apparatus according to claim 1,
wherein the recycling system comprises a first recovery part which recovers the liquid material ejected from the nozzle.

3. The coating apparatus according to claim 1,
wherein the recycling system comprises a second recovery part which recovers the liquid material held inside the nozzle.

4. The coating apparatus according to claim 3,
wherein the nozzle comprises a vent part which communicates the inside and outside of the nozzle, and
the second recovery part recovers the liquid material via the vent part.

5. The coating apparatus according to claim 1,
wherein the supplying system comprises a flow path connected to the coating part and allows the liquid material to flow therethrough, and
the recycling system comprises a third recovery part which recovers the liquid material from the flow path.

6. The coating apparatus according to claim 1,
wherein the supplying system comprises a storing part which stores the liquid material, and
the recycling system comprises a second flow path which transfers the recovered liquid material to the storing part.

7. The coating apparatus according to claim 6,
wherein the storing part comprises a stirrer which stirs the liquid material stored in the storing part.

8. The coating apparatus according to claim 1,
wherein the supplying system comprises a degassing part which removes a gaseous component contained in the liquid material, and
the recycling system comprises a third flow path which transfers the recovered liquid material to the degassing part.

9. The coating apparatus according to claim 8,
wherein the supplying system comprises a storing part which stores the liquid material, and
the degassing part is provided on a downstream side of a supply path of the liquid material, relative to the storing part.

10. The coating apparatus according to claim 8,
wherein the supplying system comprises a storing part which stores the liquid material, and
the degassing part is connected to the storing part via a second path which is different from a supply path of the liquid material.

11. A coating method comprising:
an ejection step in which a liquid material containing an oxidizable metal and a solvent is ejected from a nozzle provided on a coating part to a substrate;
a supplying step in which the liquid material is supplied to the coating part using a supplying system for the liquid material; and
a recycling step in which the liquid material is recovered from at least one of the supplying system and the coating part, and the recovered liquid material is supplied to at least one of the supplying system and the coating part.

12. The coating method according to claim 11,
wherein the recycling step comprises a first recovering step in which the liquid material ejected from the nozzle is recovered.

13. The coating method according to claim 11,
wherein the recycling step comprises a second recovering step in which the liquid material held inside the nozzle is recovered.

14. The coating method according to claim 13,
wherein the nozzle comprises a vent part which communicates the inside and outside of the nozzle, and
the second step comprises recovering the liquid material via the vent part.

15. The coating method according to claim 11,
wherein the supplying step comprises allowing the liquid material to flow via a flow path connected to the coating part, and
the recycling step comprises a third recovery step in which the liquid material is recovered from the flow path.

16. The coating method according to claim 11,
wherein the supplying step comprises a storing step in which the liquid material is stored in a storing part.

17. The coating method according to claim 16,
wherein the storing step comprises a stirring step in which the stored liquid material is stirred.

18. The coating method according to claim 1
wherein the supplying step comprises a degassing step in which a gaseous component contained in the liquid material is removed.

19. The coating method according to claim 18,
wherein the supplying step comprises a storing step in which the liquid material is stored in a storing part, and
the degassing step comprises removing the gaseous component on a downstream side of a supply path of the liquid material, relative to the storing part.

20. The coating method according to claim 18,
wherein the supplying step comprises a storing step in which the liquid material is stored in a storing part, and
the degassing step comprises removing the gaseous component on a second path which is connected to the storing part and is different from a supply path of the liquid material.
